(19) United States
(12) Patent Application Publication
(10) Pub. No.: US 2026/0190478 A1
(43) Pub. Date: Jul. 2, 2026

(54) SEMICONDUCTOR DEVICE

(71) Applicant: Samsung Electronics Co., Ltd., Suwon-si (KR)

(72) Inventor: Seungmin SONG, Suwon-si (KR)

(73) Assignee: Samsung Electronics Co., Ltd., Suwon-si (KR)

(21) Appl. No.: 19/259,482

(22) Filed: Jul. 3, 2025

(30) Foreign Application Priority Data
Dec. 31, 2024 (KR) 10-2024-0202918

(51) Int. Cl. H10D 84/90; H10D 89/10

(52) U.S. Cl. CPC H10D 84/929; H10D 84/953; H10D 84/981; H10D 89/10

(57) ABSTRACT

A semiconductor device includes a substrate including an active pattern, a channel pattern being on the active pattern and including a plurality of semiconductor patterns vertically spaced apart from each other, a source/drain pattern connected to the plurality of semiconductor patterns, a gate electrode on the plurality of semiconductor patterns and including an inner electrode and an outer electrode, the inner electrode interposed between a pair of semiconductor patterns that are adjacent to each other, and an outer electrode on an uppermost semiconductor pattern among the plurality of semiconductor patterns, and an inner spacer interposed between the inner electrode and the source/drain pattern, wherein the source/drain pattern includes a first semiconductor layer in contact with the plurality of semiconductor patterns, a second semiconductor layer on the first semiconductor layer, and a third semiconductor layer on the second semiconductor layer.

### CROSS-REFERENCE TO RELATED APPLICATIONS

This U.S. non-provisional patent application claims priority under 35 U.S.C. §119 of Korean Patent Application No. 10-2024-0202918, filed on Dec. 31, 2024, the entire contents of which are hereby incorporated by reference.

### BACKGROUND

The present disclosure herein relates to semiconductor devices, and more particularly, to semiconductor devices including a field effect transistor.

A semiconductor device includes an integrated circuit composed of metal-oxide-semiconductor field effect transistors (MOSFETs). As a size and a design rule of the semiconductor device are gradually decreasing, scaling down of the metal-oxide-semiconductor field effect transistors is also gradually being accelerated. As the metal-oxide-semiconductor field effect transistors are gradually reduced, operation characteristics of the semiconductor device may be deteriorated. Accordingly, research on various methods for overcoming limitation caused by higher-integration of the semiconductor device and forming the semiconductor device with improved performance is being conducted.

### SUMMARY

Some example embodiments of the present disclosure provide semiconductor devices with improved electrical characteristics.

Technical aspects of the inventive concepts are not limited to the aspect mentioned above, and other technical aspects that are not mentioned may be clearly understood from description below by those skilled in the art.

According to an example embodiment of the inventive concepts, a semiconductor device includes a substrate including an active pattern, a channel pattern being on the active pattern, the channel pattern including a plurality of semiconductor patterns vertically spaced apart from each other, a source/drain pattern connected to the plurality of semiconductor patterns, a gate electrode being on the plurality of semiconductor patterns, the gate electrode including an inner electrode and an outer electrode, the inner electrode interposed between a pair of semiconductor patterns that are adjacent to each other among the plurality of semiconductor patterns, an outer electrode on an uppermost semiconductor pattern among the plurality of semiconductor patterns, and an inner spacer interposed between the inner electrode and the source/drain pattern, wherein the source/drain pattern includes a first semiconductor layer in contact with the plurality of semiconductor patterns, a second semiconductor layer on the first semiconductor layer, and a third semiconductor layer on the second semiconductor layer, the inner spacer has a first tip length in a first direction, the first semiconductor layer has a second tip length in the first direction, and the second tip length is greater than the first tip length.
According to an example embodiment of the inventive concepts, a semiconductor device includes a substrate including a PMOSFET region, an active pattern on the PMOSFET region, a channel pattern being on the active pattern, the channel pattern including a plurality of semiconductor patterns vertically spaced apart from each other, a source/drain pattern connected to the plurality of semiconductor patterns, a gate electrode being on the plurality of semiconductor patterns, the gate electrode including an inner electrode interposed between a pair of semiconductor patterns that are adjacent to each other among the plurality of semiconductor patterns, an outer electrode on an uppermost semiconductor pattern among the plurality of semiconductor patterns, a gate insulating layer between the gate electrode and the semiconductor patterns adjacent to each other, and an inner spacer interposed between the source/drain pattern and the gate insulating layer surrounding the inner electrode, wherein the source/drain pattern includes a first semiconductor layer in contact with each of the plurality of semiconductor patterns, the inner spacer has a first horizontal width in a first direction, the first semiconductor layer has a second horizontal width in the first direction, and the second horizontal width is different from the first horizontal width.

According to an example embodiment of the inventive concepts, a semiconductor device includes a first active pattern on a first active region of a substrate and a second active pattern on a second active region of the substrate, an element separation layer filling a trench defining the first and second active patterns, a first channel pattern on the first active pattern and a second channel pattern on the second active pattern, each of the first and second channel patterns including a first semiconductor pattern, a second semiconductor pattern and a third semiconductor pattern vertically spaced apart from each other, a first source/drain pattern connected to the first channel pattern and a second source/drain pattern connected to the second channel pattern, a gate electrode on the first to third semiconductor patterns, a gate insulating layer between the first to third semiconductor patterns and the gate electrode, a first inner spacer interposed between the gate insulating layer and the first source/drain pattern, and a second inner spacer interposed between the gate insulating layer and the second source/drain pattern, a gate spacer on a sidewall of the gate electrode, a gate capping pattern on an upper surface of the gate electrode, an interlayered insulating layer on the gate capping pattern, an active contact penetrating the interlayered insulating layer to be electrically connected to each of the first source/drain pattern and the second source/drain pattern, a metal-semiconductor compound layer interposed between the active contact and the first source/drain pattern, and between the active contact and the second source/drain pattern, a gate contact penetrating the interlayered insulating layer and the gate capping pattern to be electrically connected to the gate electrode, a first metal layer being on the interlayered insulating layer, the first metal layer including power wires, the first wires electrically connected to the active contact and the gate contact, and a second metal layer on the first metal layer, wherein the second metal layer includes second wires electrically connected to the first metal layer, the second active region is a PMOSFET region, the second source/drain pattern includes a first semiconductor layer in contact with the first to third semiconductor patterns, a second semiconductor layer on the first semiconductor layer, and a third semiconductor layer on the second semiconductor layer, the second inner spacer has a silicon nitride-based insulating material, and the second source/drain pattern is spaced apart from the gate electrode by the second inner spacer.

According to an example embodiment of the inventive concepts, a method of manufacturing a semiconductor device includes forming an active region on a substrate, forming a channel pattern by stacking a plurality of semiconductor patterns to be spaced apart from each other, forming a source/drain pattern on a side of the channel pattern so that the source/drain pattern is connected to the plurality of semiconductor patterns, forming a gate electrode on the plurality of semiconductor patterns, the gate electrode including an inner electrode and an outer electrode, the inner electrode interposed between a pair semiconductor patterns that are adjacent to each other, among the plurality of semiconductor patterns, the outer electrode on an uppermost semiconductor pattern among the plurality of semiconductor patterns, and interposing an inner spacer between the inner electrode and the source/drain pattern, wherein the forming a source/drain pattern including forming a first semiconductor layer in contact with the plurality of semiconductor patterns, forming a second semiconductor layer on the first semiconductor layer, and forming a third semiconductor layer on the second semiconductor layer, the forming an inner spacer forms the inner spacer to have a first tip length in a first direction, and the forming a first semiconductor layer forms the first semiconductor layer to have a second tip length in the first direction, the second tip length is smaller than the first tip length.

The forming a third semiconductor layer may form the third semiconductor layer to have a greater germanium (Ge) concentration than the first semiconductor layer and the second semiconductor layer.

### BRIEF DESCRIPTION OF THE FIGURES

The accompanying drawings are included to provide a further understanding of the inventive concepts, and are incorporated in and constitute a part of this specification. The drawings illustrate some example embodiments of the inventive concepts and, together with the description, serve to explain principles of the inventive concepts. In the drawings:

FIGS. 1 to 3 are conceptual diagrams for describing logic cells of a semiconductor device according to some example embodiments of the inventive concepts;

FIG. 4 is a plan view for describing a semiconductor device according to an example embodiment of the inventive concepts;

FIGS. 5A to 5D are cross-sectional views taken along line A-A′, line B-B′, line C-C′ and line D-D′ of FIG. 4, respectively;

FIG. 6 is an enlarged diagram illustrating an example embodiment of region M of FIG. 5B;

FIGS. 7A to 12D are cross-sectional views for describing a method for manufacturing a semiconductor device according to an example embodiment of the inventive concepts; and

FIGS. 13 to 17 are enlarged diagrams for describing a method for forming region M of FIG. 10B.

### DETAILED DESCRIPTION

Hereinafter, some example embodiments according to the inventive concepts will be described in more detail with reference to the accompanying drawings in order to more for example describe the inventive concepts.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

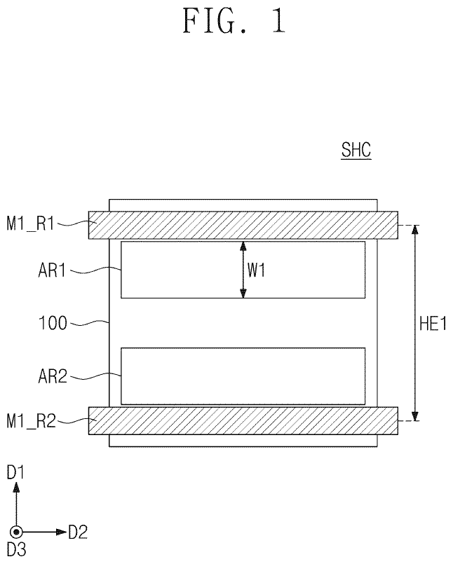

FIGS. 1 to 3 are conceptual diagrams for describing logic cells of a semiconductor device according to some example embodiments of the inventive concepts.

Referring to FIG. 1, a single height cell SHC may be provided. For example, a first power wire M1_R1 and a second power wire M1_R2 may be provided on a substrate 100. The first power wire M1_R1 may be a path through which a source voltage VSS, for example, a ground voltage is provided. The second power wire M1_R2 may be a path through which a drain voltage VDD, for example, a power voltage is provided.

The single height cell SHC may be defined between the first power wire M1_R1 and the second power wire M1_R2. The single height cell SHC may include one first active region AR1 and one second active region AR2. Any one of the first and second active regions AR1 and AR2 may be a PMOSFET region, and the other one of the first and second active regions AR1 and AR2 may be an NMOSFET region. In other words, the single height cell SHC may have a structure in which a CMOS is provided between the first power wire M1_R1 and the second power wire M1_R2.

Each of the first and second active regions AR1 and AR2 may have a first width W1 in a first direction D1. A length of the single height cell SHC in the first direction D1 may be defined as a first height HE1. The first height HE1 may be substantially the same as a distance (for example, a pitch) between the first power wire M1_R1 and the second power wire M1_R2.

The single height cell SHC may constitute one logic cell. In the present specification, the logic cell may mean a logic device (e.g., AND, OR, XOR, XNOR, an inverter, or the like) that performs a specific function. That is, the logic cell may include transistors for constituting the logic device, and wires connecting the transistors each other.

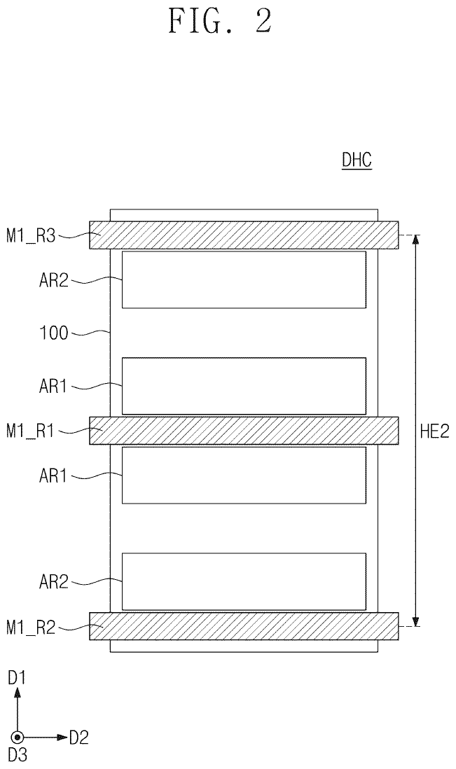

Referring to FIG. 2, a double height cell DHC may be provided. For example, the first power wire M1_R1, the second power wire M1_R2 and a third power wire M1_R3 may be provided on the substrate 100. The first power wire M1_R1 may be disposed between the second power wire M1_R2 and the third power wire M1_R3. The third power wire M1_R3 may be a path through which the source voltage VSS is provided.

The double height cell DHC may be defined between the second power wire M1_R2 and the third power wire M1_R3. The double height cell DHC may include two first active regions AR1 and two second active regions AR2.

One of the two second active regions AR2 may be adjacent to the second power wire M1_R2. The other one of the two second active regions AR2 may be adjacent to the third power wire M1_R3. The two first active regions AR1 may be adjacent to the first power wire M1_R1. On a plan view, the first power wire M1_R1 may be disposed between the two first active regions AR1.

A length of the double height cell DHC in the first direction D1 may be defined as a second height HE2. The second height HE2 may be about twice longer than the first height HE1 of FIG. 1. The two first active regions AR1 of the double height cell DHC may operate together as one active region.

According to an example embodiment, the double height cell DHC illustrated in FIG. 2 may be defined as a multi-height cell. Although not shown, the multi-height cell may include a triple height cell of which a cell height is about three times longer than that of the single height cell SHC.

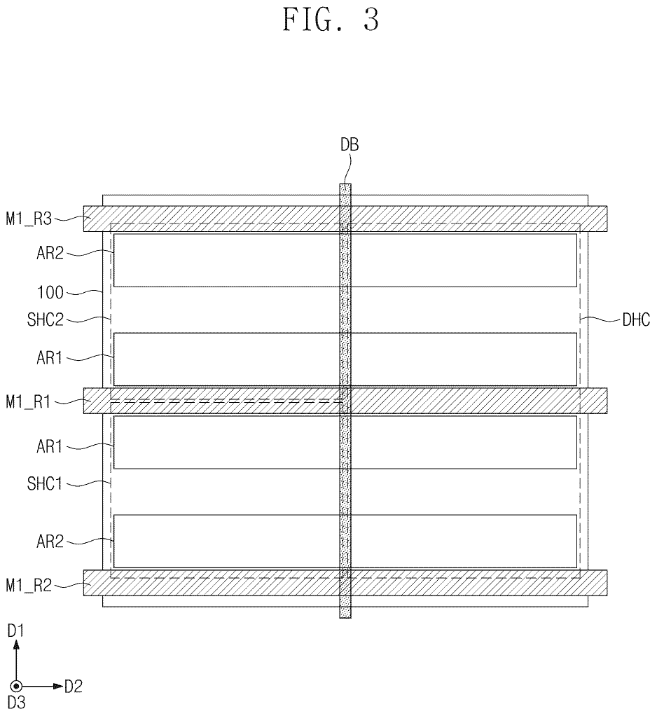

Referring to FIG. 3, a first single height cell SHC1, a second single height cell SHC2, and the double height cell DHC may be two-dimensionally disposed on the substrate 100. The first single height cell SHC1 may be disposed between the first and second power wires M1_R1 and M1_R2. The second single height cell SHC2 may be disposed between the first and third power wires M1_R1 and M1_R3. The second single height cell SHC2 may be adjacent to the first single height cell SHC1 in the first direction D1.

The double height cell DHC may be disposed between the second and third power wires M1_R2 and M1_R3. The double height cell DHC may be adjacent to the first and second single height cells SHC1 and SHC2 in a second direction D2.

A separation structure DB may be provided between the first single height cell SHC1 and the double height cell DHC, and between the second single height cell SHC2 and the double height cell DHC. An active region of the double height cell DHC may be electrically separated from an active region of each of the first and second single height cells SHC1 and SHC2 by the separation structure DB.

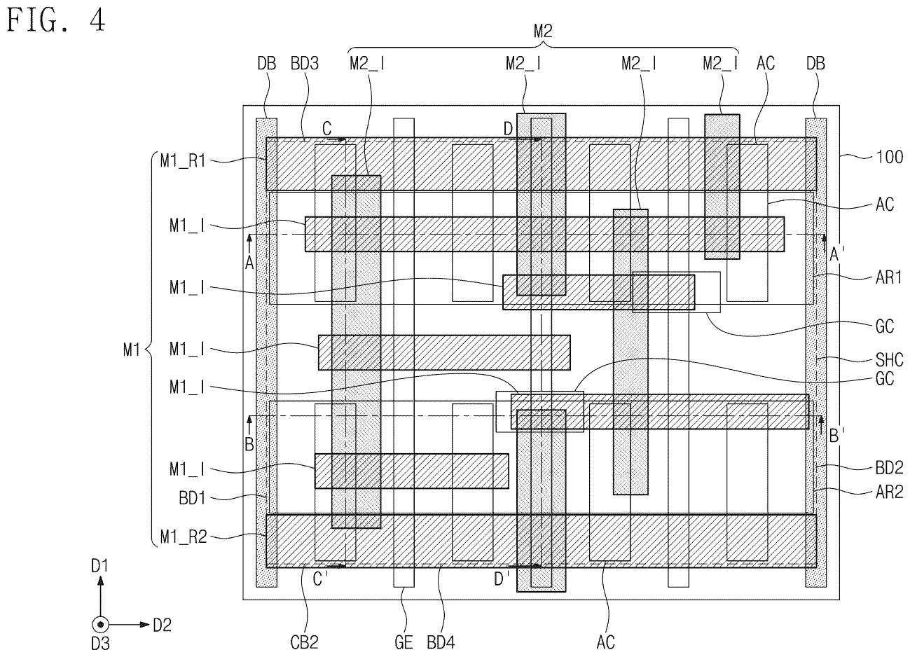

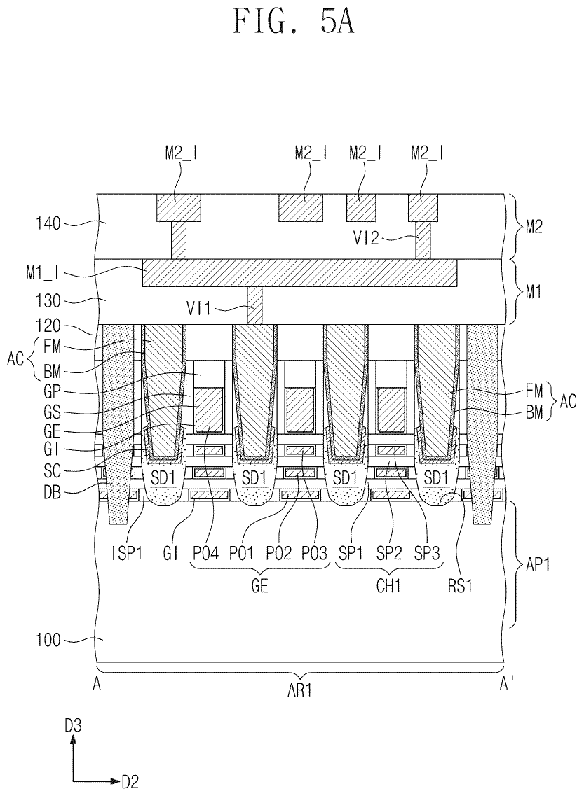

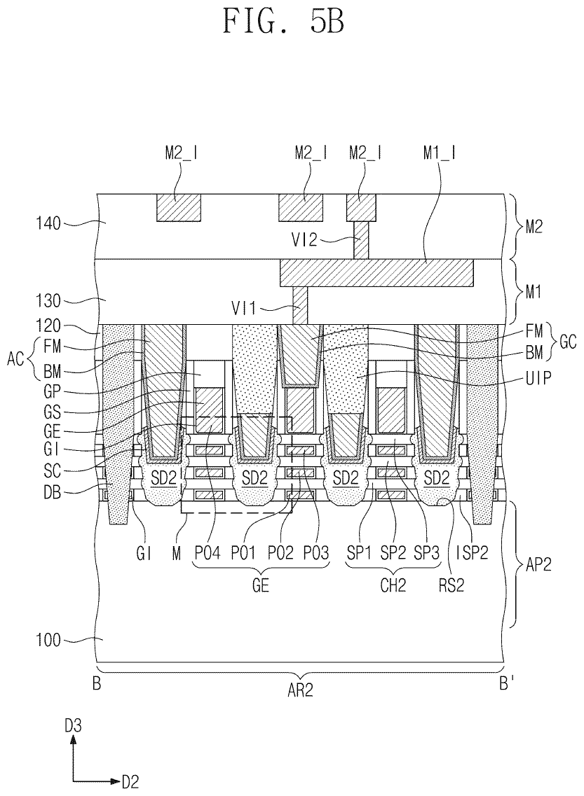

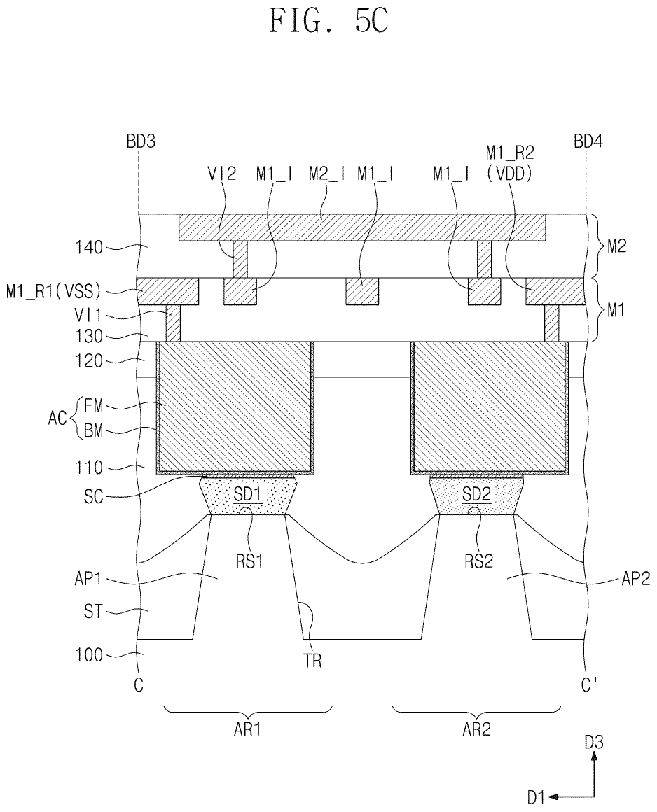

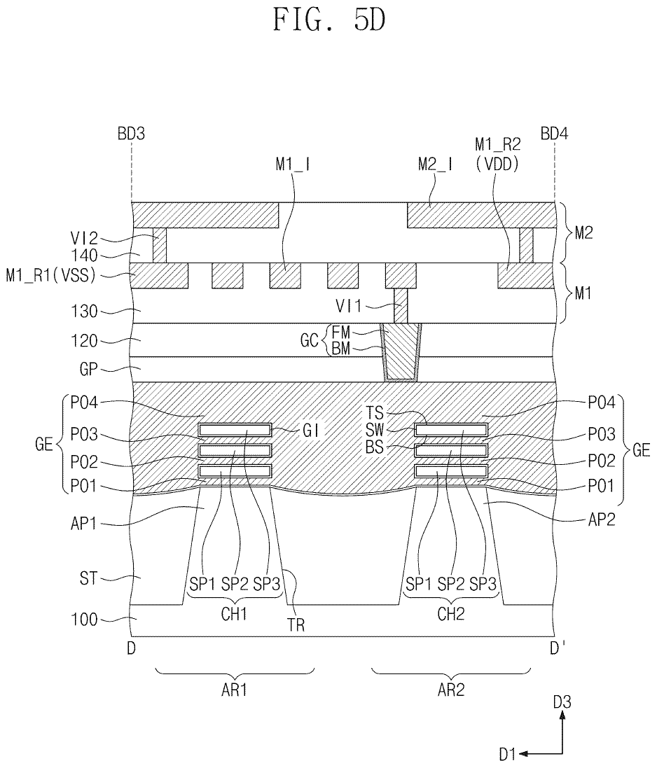

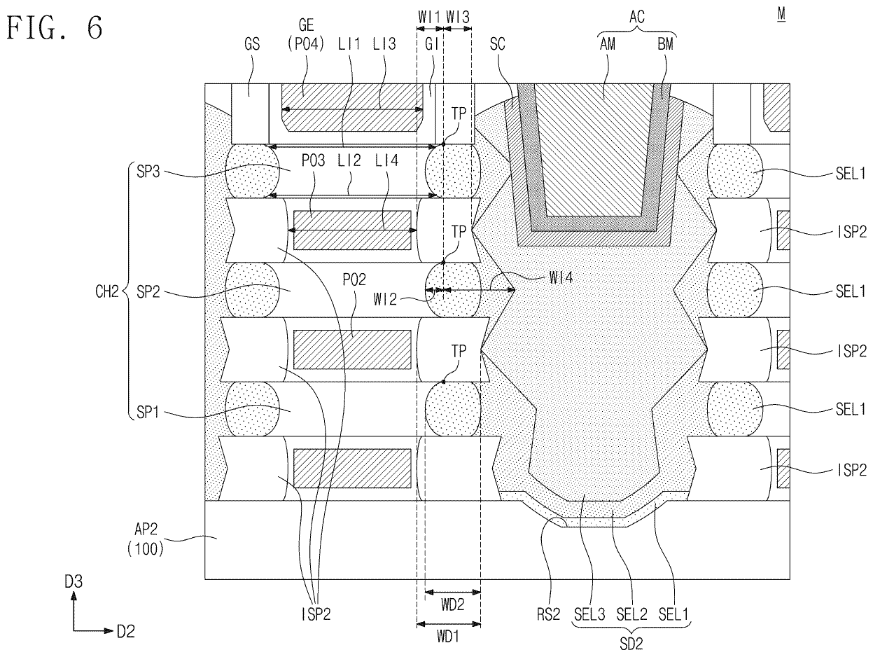

FIG. 4 is a plan view for describing a semiconductor device according to an example embodiment of the inventive concepts. FIGS. 5A to 5D are cross-sectional views taken along line A-A′, line B-B′, line C-C′ and line D-D′ of FIG. 4, respectively. FIG. 6 is an enlarged diagram illustrating an example embodiment of region M of FIG. 5B. The semiconductor device illustrated in FIGS. 4 and 5A to 5D is an example more specifically illustrating the single height cell SHC of FIG. 1.

Referring to FIGS. 4 and 5A to 5D, the single height cell SHC may be provided on the substrate 100. Logic transistors that constitute a logic circuit may be disposed on the single height cell SHC. The substrate 100 may be a semiconductor substrate or a compound semiconductor substrate including silicon, germanium, silicon-germanium, or the like. For example, the substrate 100 may be a silicon substrate.

The substrate 100 may include the first active region AR1 and the second active region AR2. Each of the first and second active regions AR1 and AR2 may extend in the second direction D2. According to an example embodiment, the first active region AR1 may be an NMOSFET region, and the second active region AR2 may be a PMOSFET region.

A first active pattern AP1 and a second active pattern AP2 may be defined by a trench TR formed on the substrate 100. The first active pattern AP1 may be provided on the first active region AR1, and the second active pattern AP2 may be provided on the second active region AR2. The first and second active patterns AP1 and AP2 may extend in the second direction D2. The first and second active patterns AP1 and AP2 may be parts vertically protruding as parts of the substrate 100.

An element separation layer ST may be provided on the substrate 100. The element separation layer ST may fill the trench TR. The element separation layer ST may include a silicon oxide layer. The element separation layer ST may not cover first and second channel patterns CH1 and CH2 to be described later.

A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2, and a third semiconductor pattern SP3 sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may include silicon (Si), germanium (Ge), or silicon-germanium (SiGe). For example, each of the first to third semiconductor patterns SP1, SP2, and SP3 may include crystalline silicon (e.g., single-crystalline silicon). According to an example embodiment of the inventive concepts, the first to third semiconductor patterns SP1, SP2, and SP3 may be stacked nanosheets.

A plurality of first source/drain patterns SD1 may be provided on the first active pattern AP1. A plurality of first recesses RS1 may be formed on the first active pattern AP1. The first source/drain patterns SD1 may be provided in the first recesses RS1, respectively. The first source/drain patterns SD1 may be impurity regions having a first conductive type (e.g., an N-type). The first channel pattern CH1 may be interposed between a pair of first source/drain patterns SD1. In other words, the stacked first to third semiconductor patterns SP1, SP2, and SP3 may connect the pair of first source/drain patterns SD1 each other.

A plurality of second source/drain patterns SD2 may be provided on the second active pattern AP2. A plurality of second recesses RS2 may be formed on the second active pattern AP2. The second source/drain patterns SD2 may be provided in the second recesses RS2, respectively. The second source/drain patterns SD2 may be impurity regions having a second conductive type (e.g., a P-type). The second channel pattern CH2 may be interposed between a pair of second source/drain patterns SD2. In other words, the stacked first to third semiconductor patterns SP1, SP2, and SP3 may connect the pair of second source/drain patterns SD2 each other.

The first and second source/drain patterns SD1 and SD2 may be epitaxial patterns formed in a selective epitaxial growth (SEG) process. For example, an upper surface of each of the first and second source/drain patterns SD1 and SD2 may be located at a higher level than an upper surface of the third semiconductor pattern SP3. For another example, the upper surface of at least one of the first or second source/drain pattern SD1 or SD2 may be located at the substantially same level as the upper surface of the third semiconductor pattern SP3.

According to an example embodiment of the inventive concepts, the first source/drain patterns SD1 may include the same semiconductor element (e.g., Si) as the substrate 100. The second source/drain patterns SD2 may include a semiconductor element (e.g., SiGe) having a greater lattice parameter than a semiconductor element (e.g., Si) of the substrate 100. Accordingly, a pair of second source/drain patterns SD2 may supply a compressive stress to the second channel pattern CH2 therebetween.

According to an example embodiment of the inventive concepts, a sidewall of the second source/drain pattern SD2 may have an uneven embossed form. In other words, the sidewall of the second source/drain pattern SD2 may have a wavy profile. The sidewall of the second source/drain pattern SD2 may protrude toward the first to third semiconductor patterns SP1, SP2, and SP3 of the second channel pattern CH2.

Gate electrodes GE may be provided on the first and second channel patterns CH1 and CH2. Each of the gate electrodes GE may cross the first and second channel patterns CH1 and CH2, and may extend in the first direction D1. Each of the gate electrodes GE may vertically overlap the first and second channel patterns CH1 and CH2. The gate electrodes GE may be arranged having a first pitch in the second direction D2.

The gate electrode GE may include a first inner electrode PO1 interposed between the active pattern AP1 or AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring to FIG. 5D, the gate electrode GE may be provided on an upper surface TS, a bottom surface BS, and both sidewalls SW of each of the first to third semiconductor patterns SP1, SP2, and SP3. In other words, a transistor according to the present example embodiment may be a three-dimensional field effect transistor (e.g., a Multi-Bridge Channel Field-Effect Transistor (MBCFET) or a Gate-All-Around Field-Effect Transistor (GAAFET)), in which the gate electrode GE three-dimensionally surrounds a channel thereof.

First inner spacers ISP1 may be interposed between the first source/drain pattern SD1 and the first to third inner electrodes PO1, PO2, and PO3 of the gate electrode GE, respectively, on the first active region AR1. Each of the first to third inner electrodes PO1, PO2, and PO3 of the gate electrode GE may be spaced apart from the first source/drain pattern SD1 with the first inner spacer ISP1 therebetween. The first inner spacer ISP1 may reduce or prevent leakage current from the gate electrode GE. For example, the first inner spacer ISP1 may include at least one of silicon oxide, silicon nitride or silicon oxynitride.

Second inner spacers ISP2 may be interposed between the second source/drain pattern SD2 and the first to third inner electrodes PO1, PO2, and PO3 of the gate electrode GE, respectively, on the second active region AR2. Each of the first to third inner electrodes PO1, PO2, and PO3 of the gate electrode GE may be spaced apart from the second source/drain pattern SD2 with the second inner spacer ISP2 therebetween. The second inner spacer ISP2 may reduce or prevent leakage current from the gate electrode GE, and generation of parasitic capacitance. For example, the second inner spacer ISP2 may include at least one of silicon oxide, silicon nitride or silicon oxynitride. For example, the second inner spacer ISP2 may include a silicon nitride-based insulating material. The second inner spacer ISP2 according to an example embodiment will be described later with reference to FIG. 6 in detail.

Referring back to FIGS. 4 and 5A to 5D, a pair of gate spacers GS may be disposed on both sidewalls of the outer electrode PO4 of the gate electrode GE, respectively. The gate spacers GS may extend along the gate electrode GE in the first direction D1. Upper surfaces of the gate spacers GS may be higher than an upper surface of the gate electrode GE. The upper surfaces of the gate spacers GS may be coplanar with an upper surface of a first interlayered insulating layer 110 to be described later. According to an example embodiment, the gate spacers GS may include at least one of SiCN, SiCON, or SiN. According to another example embodiment, the gate spacers GS may include a multi-layer composed of at least two of SiCN, SiCON, or SiN.

A gate capping pattern GP may be provided on the gate electrode GE. The gate capping pattern GP may extend along the gate electrode GE in the first direction D1. The gate capping pattern GP may include a material having etching selectivity with respect to first and second interlayered insulating layers 110 and 120 to be described later. For example, the gate capping pattern GP may include at least one of SiON, SiCN, SiCON, or SiN.

A gate insulating layer GI may be interposed between the gate electrode GE and the first channel pattern CH1, and between the gate electrode GE and the second channel pattern CH2. The gate insulating layer GI may cover the upper surface TS, the bottom surface BS, and the both sidewalls SW of each of the first to third semiconductor patterns SP1, SP2, and SP3. The gate insulating layer GI may cover an upper surface of the element separation layer ST under the gate electrode GE.

According to an example embodiment of the inventive concepts, the gate insulating layer GI may include a silicon oxide layer, a silicon oxynitride layer, and/or a high-dielectric layer. For example, the gate insulating layer GI may have a structure in which a silicon oxide layer and a high-dielectric layer are stacked. The high-dielectric layer may include a high-dielectric material having a higher dielectric constant than the silicon oxide layer. For example, the high-dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

According to another example embodiment, the semiconductor device may include a negative capacitance FET using a negative capacitor. For example, the gate insulating layer GI may include a ferroelectric material layer having ferroelectric characteristics, and/or a paraelectric material layer having paraelectric characteristics.

The ferroelectric material layer may have a negative capacitance, and the paraelectric material layer may have a positive capacitance. For example, when at least two capacitors are serially connected to each other, and each of the capacitors has a positive capacitance value, the total capacitance becomes smaller than capacitance of each individual capacitor. However, when at least one of two or more capacitors serially connected to each other has a negative capacitance value, the total capacitance may have a positive value and may be greater than an absolute value of capacitance of each individual capacitor.

When a ferroelectric material layer having a negative capacitance and a paraelectric material layer having a positive capacitance are serially connected to each other, the total capacitance of the ferroelectric material layer and the paraelectric material layer serially connected to each other may increase. A transistor including the ferroelectric material layer may have a subthreshold swing (SS) smaller than about 60 mV/decade at room temperature by using a phenomenon that the total capacitance increases.

The ferroelectric material layer may have ferroelectric characteristics. For example, the ferroelectric material layer may include at least one of hafnium oxide, hafnium zirconium oxide, barium strontium titanium oxide, barium titanium oxide, or lead zirconium titanium oxide. Here, the hafnium zirconium oxide may be, for example, hafnium oxide doped with zirconium (Zr). For another example, the hafnium zirconium oxide may be a compound of hafnium (Hf), zirconium (Zr) and oxygen (O).

The ferroelectric material layer may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be changed depending on which ferroelectric material the ferroelectric material layer includes.

When the ferroelectric material layer includes hafnium oxide, the dopant included in the ferroelectric material layer may include, for example, at least one of gadolinium (Gd), silicon (Si), zirconium (Zr), aluminum (Al), or yttrium (Y).

When the dopant is aluminum (Al), the ferroelectric material layer may include aluminum of about 3 at % to about 8 at %. Here, a ratio of the dopant may be a ratio of aluminum to a sum of hafnium and aluminum.

When the dopant is silicon (Si), the ferroelectric material layer may include silicon of about 2 at % to about 10 at %. When the dopant is yttrium (Y), the ferroelectric material layer may include yttrium (Y) of about 2 at % to about 10 at %. When the dopant is gadolinium (Gd), the ferroelectric material layer may include gadolinium (Gd) of about 1 at % to about 7 at %. When the dopant is zirconium (Zr), the ferroelectric material layer may include zirconium (Zr) of about 50 at % to about 80 at %.

The paraelectric material layer may have paraelectric characteristics. For example, the paraelectric material layer may include at least one of silicon oxide or metal oxide having a high-dielectric constant. For example, the metal oxide included in the paraelectric material layer may include at least one of hafnium oxide, zirconium oxide or aluminum oxide, but example embodiments of the inventive concepts are not limited thereto.

The ferroelectric material layer and the paraelectric material layer may include the same material. The ferroelectric material layer may have ferroelectric characteristics, but the paraelectric material layer may not have the ferroelectric characteristics. For example, when the ferroelectric material layer and the paraelectric material layer include hafnium oxide, a crystal structure of hafnium oxide included in the ferroelectric material layer is different from a crystal structure of the hafnium oxide included in the paraelectric material layer.

The ferroelectric material layer may have a thickness suitable for showing ferroelectric characteristics. For example, the ferroelectric material layer may have a thickness of about 0.5 nm to about 10 nm, but example embodiments of the inventive concepts are not limited thereto. Because each of the ferroelectric materials may have a critical thickness that begins to show the ferroelectric characteristics, the ferroelectric material layer may have a thickness different depending on a ferroelectric material thereof.

For example, the gate insulating layer GI may include one ferroelectric material layer. For another example, the gate insulating layer GI may include a plurality of ferroelectric material layers spaced apart from each other. The gate insulating layer GI may have a stack layer structure in which a plurality of ferroelectric material layers and a plurality of paraelectric material layers are alternately stacked.

Referring back to FIGS. 4 and 5A to 5D, the gate electrode GE may include a first metal pattern, and a second metal pattern on the first metal pattern. The first metal pattern may be provided on the gate insulating layer GI to be adjacent to the first to third semiconductor patterns SP1, SP2, and SP3. The first metal pattern may include a work-function metal that controls a threshold voltage of a transistor. A targeted threshold voltage of the transistor may be achieved by controlling a thickness and a composition of the first metal pattern. For example, the first to third inner electrodes PO1, PO2, and PO3 of the gate electrode GE may be composed of the first metal pattern, which is made of the work-function metal.

The first metal pattern may include a metal nitride layer. For example, the first metal pattern may include nitrogen (N) and at least one metal selected from the group consisting of titanium (Ti), tantalum (Ta), aluminum (Al), tungsten (W), and molybdenum (Mo). Moreover, the first metal pattern may further include carbon (C). The first metal pattern may include a plurality of stacked work-function metal layers.

The second metal pattern may include metal having lower resistance than that of the first metal pattern. For example, the second metal pattern may include at least one metal selected from the group consisting of titanium (Ti), tantalum (Ta), aluminum (Al), and tungsten (W). For example, the outer electrode PO4 of the gate electrode GE may include the first metal pattern and the second metal pattern on the first metal pattern.

The first interlayered insulating layer 110 may be provided on the substrate 100. The first interlayered insulating layer 110 may cover the gate spacers GS and the first and second source/drain patterns SD1 and SD2. An upper surface of the first interlayered insulating layer 110 may be substantially coplanar with an upper surface of the gate capping pattern GP and an upper surface of the gate spacer GS. The second interlayered insulating layer 120 covering the gate capping pattern GP may be disposed on the first interlayered insulating layer 110. A third interlayered insulating layer 130 may be provided on the second interlayered insulating layer 120. A fourth interlayered insulating layer 140 may be provided on the third interlayered insulating layer 130. For example, the first to fourth interlayered insulating layers 110, 120, 130, and 140 may each include a silicon oxide layer.

The single height cell SHC may have a first boundary BD1 and a second boundary BD2 opposed to each other in the second direction D2. The first and second boundaries BD1 and BD2 may extend in the first direction D1. The single height cell SHC may have a third boundary BD3 and a fourth boundary BD4 opposed to each other in the first direction D1. The third and fourth boundaries BD3 and BD4 may extend in the second direction D2.

A pair of separation structures DB opposed to each other in the second direction D2 may be provided on both sides of the single height cell SHC. For example, the pair of separation structures DB may be provided on the first and second boundaries BD1 and BD2 of the single height cell SHC, respectively. The separation structure DB may extend parallel to the gate electrodes GE in the first direction D1. A pitch between the separation structure DB and the gate electrode GE adjacent thereto may be the same as the first pitch.

The separation structure DB may penetrate the first and second interlayered insulating layers 110 and 120 to extend to the insides of the first and second active patterns AP1 and AP2. The separation structure DB may penetrate an upper portion of each of the first and second active patterns AP1 and AP2. The separation structure DB may electrically separate an active region of single height cell SHC from an active region of another cell adjacent thereto.

Active contacts AC penetrating the first and second interlayered insulating layers 110 and 120 to be electrically connected to the first and second source/drain patterns SD1 and SD2, respectively, may be provided. A pair of active contacts AC may be provided on both sides of the gate electrode GE, respectively. On a plan view, the active contact AC may have a form of a bar extending in the first direction D1.

The active contact AC may be a self-aligned contact. In other words, the active contact AC may be formed self-aligned using the gate capping pattern GP and the gate spacer GS. For example, the active contact AC may at least partially cover a sidewall of the gate spacer GS. Although not shown, the active contact AC may partially cover an upper surface of the gate capping pattern GP.

A metal-semiconductor compound layer SC, for example, a silicide layer may be interposed between the active contact AC and the first source/drain pattern SD1, and between the active contact AC and the second source/drain pattern SD2. The active contact AC may be electrically connected to the source/drain pattern SD1 or SD2 through the metal-semiconductor compound layer SC. For example, the metal-semiconductor compound layer SC may include at least one of titanium-silicide, tantalum-silicide, tungsten-silicide, nickel-silicide, or cobalt-silicide.

Gate contacts GC penetrating the second interlayered insulating layer 120 and the gate capping pattern GP to be electrically connected to the gate electrodes GE, respectively, may be provided. On a plan view, the gate contacts GC may be disposed so as to overlap the first active region AR1 and the second active region AR2, respectively. For example, the gate contact GC may be provided on the second active pattern AP2 (see FIG. 5B).

According to an example embodiment of the inventive concepts, referring to FIG. 5B, an upper portion of the active contact AC adjacent to the gate contact GC may be filled with an upper insulating pattern UIP. A bottom surface of the upper insulating pattern UIP may be lower than a bottom surface of the gate contact GC. In other words, an upper surface of the active contact AC adjacent to the gate contact GC may become lower than a bottom surface of the gate contact GC due to the upper insulating pattern UIP. Accordingly, an electric short generated by bringing the gate contact GC into contact with the active contact AC adjacent thereto may be reduced or prevented.

Each of the active contact AC and the gate contact GC may include a conductive pattern FM and a barrier pattern BM surrounding the conductive pattern FM. For example, the conductive pattern FM may include at least one metal of aluminum, copper, tungsten, molybdenum or cobalt. The barrier pattern BM may cover sidewalls and a bottom surface of the conductive pattern FM. The barrier pattern BM may include a metal layer and/or a metal nitride layer. The metal layer may include at least one of titanium, tantalum, tungsten, nickel, cobalt or platinum. The metal nitride layer may include at least one of a titanium nitride (TiN) layer, a tantalum nitride (TaN) layer, a tungsten nitride (WN) layer, a nickel nitride (NiN) layer, a cobalt nitride (CoN) layer or a platinum nitride (PtN) layer.

A first metal layer M1 may be provided in the third interlayered insulating layer 130. For example, the first metal layer M1 may include the first power wire M1_R1, the second power wire M1_R2 and first wires M1_I. Each of the wires M1_R1, M1_R2 and M1_I of the first metal layer M1 may extend parallel to each other in the second direction D2.

For example, the first and second power wires M1_R1 and M1_R2 may be provided on the third and fourth boundaries BD3 and BD4 of the single height cell SHC, respectively. The first power wire M1_R1 may extend along the third boundary BD3 in the second direction D2. The second power wire M1_R2 may extend along the fourth boundary BD4 in the second direction D2.

The first wires M1_I of the first metal layer M1 may be disposed between the first and second power wires M1_R1 and M1_R2. The first wires M1_I of the first metal layer M1 may be arranged with a second pitch in the first direction D1. The second pitch may be smaller than the first pitch. A line width of each of the first wires M1_I may be smaller than a line width of each of the first and second power wires M1_R1 and M1_R2.

The first metal layer M1 may further include first vias VI1. The first vias VI1 may be provided under the wires M1_R1, M1_R2 and M1_I of the first metal layer M1, respectively. The active contact AC and the wire of the first metal layer M1 may be electrically connected to each other through the first via VI1. The gate contact GC and the wire of the first metal layer M1 may be electrically connected to each other through the first via VI1.

The wire of the first metal layer M1 and the first via VI1 thereunder may be formed in separate processes, respectively. Each of the wire of the first metal layer M1 and the first via VI1 may be formed in a single damascene process. The semiconductor device according to the present example embodiment may be formed using processes of manufacturing a semiconductor device having a design rule less than about 20 nm.

A second metal layer M2 may be provided in the fourth interlayered insulating layer 140. The second metal layer M2 may include a plurality of second wires M2_I. Each of the second wires M2_I of the second metal layer M2 may have a form of a line or a bar extending in the first direction D1. In other words, the second wires M2_I may extend in the first direction D1 to be parallel to each other.

The second metal layer M2 may further include second vias VI2 provided under the second wires M2_I, respectively. The wire of the first metal layer M1 and the wire of the second metal layer M2 may be electrically connected to each other through the second via VI2. For example, the wire of the second metal layer M2 and the second via VI2 thereunder may be formed together in a dual damascene process.

The wire of the first metal layer M1 and the wire of the second metal layer M2 may include the same conductive material or different conductive materials. For example, the wire of the first metal layer M1 and the wire of the second metal layer M2 may include at least one metal material selected from aluminum, copper, tungsten, molybdenum, ruthenium or cobalt. Although not shown, metal layers (e.g., M3, M4, M5 and the like) stacked on the fourth interlayered insulating layer 140 may be additionally disposed. Each of the stacked metal layers may include wires for routing between cells.

The second channel pattern CH2, the second source/drain pattern SD2 and the second inner spacer ISP2 will be described with reference to FIG. 6 in more detail. Referring to FIG. 6, the second channel pattern CH2 may include the first semiconductor pattern SP1, the second semiconductor pattern SP2 and the third semiconductor pattern SP3 spaced apart from each other and vertically stacked. According to an example embodiment of the inventive concepts, the first to third semiconductor patterns SP1, SP2, and SP3 may have the same channel length. According to another example embodiment, an uppermost third semiconductor pattern SP3 among the first to third semiconductor patterns SP1, SP2, and SP3 may have the shortest channel length. A lowermost first semiconductor pattern SP1 among the first to third semiconductor patterns SP1, SP2, and SP3 may have the longest channel length.

A channel length of each of the first to third semiconductor patterns SP1, SP2, and SP3 may be longer than a gate width of each of the first to third inner electrodes PO1, PO2, and PO3 of the gate electrode GE and a gate width of the outer electrode PO4 of the gate electrode GE. The channel length may be defined as a horizontal distance in the second direction D2, and the gate width may be defined as a horizontal distance in the second direction D2.

Each of the first to third semiconductor patterns SP1, SP2, and SP3 may include concave sidewalls. Accordingly, the channel length of each of the first to third semiconductor patterns SP1, SP2, and SP3 may have a maximum length on an upper surface and a lower surface thereof, and may have a minimum length at the center thereof. Each of the first to third semiconductor patterns SP1, SP2, and SP3 may have a tip TP on the upper surface thereof.

For example, an upper surface of the third semiconductor pattern SP3 may have a first length LI1 in the second direction D2, and a lower surface of the third semiconductor pattern SP3 may have a second length LI2 in the second direction D2. The first length LI1 and the second length LI2 may correspond to the maximum length. The outer electrode PO4 of the gate electrode GE may have a third length LI3 in the second direction D2, and the third inner electrode PO3 of the gate electrode GE may have a fourth length LI4 in the second direction D2. The third inner electrode PO3 and the gate insulating layer GI surrounding the third inner electrode PO3 may have the fourth length LI4 in the second direction D2.

Each of the first length LI1 and the second length LI2 may be greater than the third length LI3 and the fourth length LI4. A minimum length in the second direction D2 of the third semiconductor pattern SP3 may be the same as or greater than the third length LI3 and the fourth length LI4.

The second source/drain pattern SD2 may include a first semiconductor layer SEL1 in contact with the first to third semiconductor patterns SP1, SP2, and SP3, a second semiconductor layer SEL2 on the first semiconductor layer SEL1, and a third semiconductor layer SEL3 on the second semiconductor layer SEL2. The first semiconductor layer SEL1 may protrude toward each of the first to third semiconductor patterns SP1, SP2, and SP3, and may have a convex side surface toward a corresponding one of the first to third semiconductor patterns SP1, SP2, and SP3.

The first semiconductor layer SEL1 may be further provided at a bottom portion of the second source/drain pattern SD2. The first semiconductor layer SEL1 provided on the bottom portion may be interposed between the second active pattern AP2 and the second semiconductor layer SEL2.

The second source/drain pattern SD2 may include silicon-germanium (SiGe). That is, the first semiconductor layer SEL1, the second semiconductor layer SEL2 and the third semiconductor layer SEL3 may all include silicon-germanium (SiGe), but may have different germanium (Ge) concentrations.

The third semiconductor layer SEL3 may have a greater germanium (Ge) concentration than the first semiconductor layer SEL1 and the second semiconductor layer SEL2. The second semiconductor layer SEL2 may have a greater germanium (Ge) concentration than the first semiconductor layer SEL1. For example, the first semiconductor layer SEL1 may have a germanium (Ge) concentration of about 2 at % to about 8 at %, or about 4 at % to about 8 at %. The second semiconductor layer SEL2 may have a germanium (Ge) concentration of about 10 at % to about 20 at %, and the third semiconductor layer SEL3 may have a germanium (Ge) concentration of about 30 at % to about 70 at %.

The second inner spacer ISP2 may be interposed between the first to third inner electrodes PO1, PO2, and PO3 and the second source/drain pattern SD2. For example, the second inner spacer ISP2 may be interposed between the gate insulating layer GI surrounding each of the first to third inner electrodes PO1, PO2, and PO3 and the second semiconductor layer SEL2 and the third semiconductor layer SEL3 of the second source/drain pattern SD2. That is, the second source/drain pattern SD2 may be spaced apart from the first to third inner electrodes PO1, PO2, and PO3 of the gate electrode GE by the second inner spacer ISP2.

The second inner spacer ISP2 may have a first tip length WI1 in the second direction D2. The first tip length WI1 of the second inner spacer ISP2 may be defined as a distance from the tip TP of the second semiconductor pattern SP2 to one sidewall of the second inner spacer ISP2 in the second direction D2. For example, the one sidewall may be a sidewall in contact with the gate insulating layer GI surrounding the third inner electrode PO3. The first semiconductor layer SEL1 may have a second tip length WI2 in the second direction D2. The second tip length WI2 of the first semiconductor layer SEL1 may be defined as a distance from the tip TP of the second semiconductor pattern SP2 to one side surface of the first semiconductor layer SEL1 in the second direction D2. The one side surface may be a side surface in contact with the second semiconductor pattern SP2. The first tip length WI1may be greater than the second tip length WI2.

The second inner spacer ISP2 may have a third tip length WI3 in an opposite direction of the second direction D2. The third tip length WI3 of the second inner spacer ISP2 may be defined as a distance from the tip TP of the second semiconductor pattern SP2 to the other sidewall of the second inner spacer ISP2. For example, the other sidewall may be a sidewall in contact with the second semiconductor layer SEL2 or the third semiconductor layer SEL3. The first semiconductor layer SEL1 and the second semiconductor layer SEL2 may have a fourth tip length WI4 in an opposite direction of the second direction D2. The fourth tip length WI4 of the first semiconductor layer SEL1 and the second semiconductor layer SEL2 may be defined as a distance from the tip TP of the second semiconductor pattern SP2 to an inner side surface of the second semiconductor layer SEL2. The fourth tip length WI4 may be greater than the third tip length WI3. The fourth tip length WI4 may be greater than the first to third tip lengths WI1, WI2 and WI3. The third tip length WI3 may be greater than the second tip length WI2. In other words, the inner side surface of the second semiconductor layer SEL2 may be spaced farther apart from the tip TP in the second direction D2 than one side surface of the second inner spacer ISP2.

The second inner spacer ISP2 may have a first horizontal width WD1 in the second direction D2. The first horizontal width WD1 may be defined as a horizontal distance from the one sidewall to the other sidewall, which are described above, of the second inner spacer ISP2. The first semiconductor layer SEL1 may have a second horizontal width WD2 in the second direction D2. The second horizontal width WD2 may be defined as a horizontal distance from the one side surface to the other side surface, which are described above, of the first semiconductor layer SEL1. The second horizontal width WD2 may be the same as or different from the first horizontal width WD1. For example, the first horizontal width WD1 may be greater than the second horizontal width WD2. For another example, the second horizontal width WD2 may be about 2 nm to about 6 nm.

The second inner spacer ISP2 may include a silicon nitride-based insulating material. The insulating material may include at least one selected from the group consisting of SiN, SiCN, SiOCN and SiBCN. The second inner spacer ISP2 may include the same insulating material as the first inner spacer ISP1 (see FIG. 5A). For another example, the second inner spacer ISP2 and the first inner spacer ISP1 (see FIG. 5A) may include the silicon nitride-based insulating material, but may include different insulating materials.

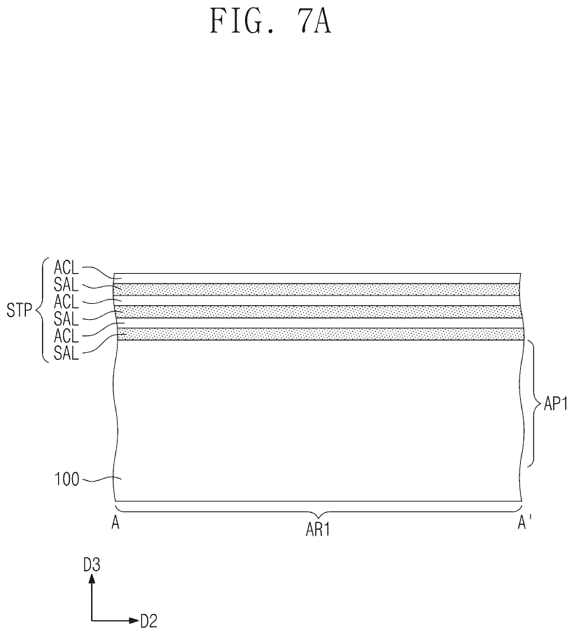

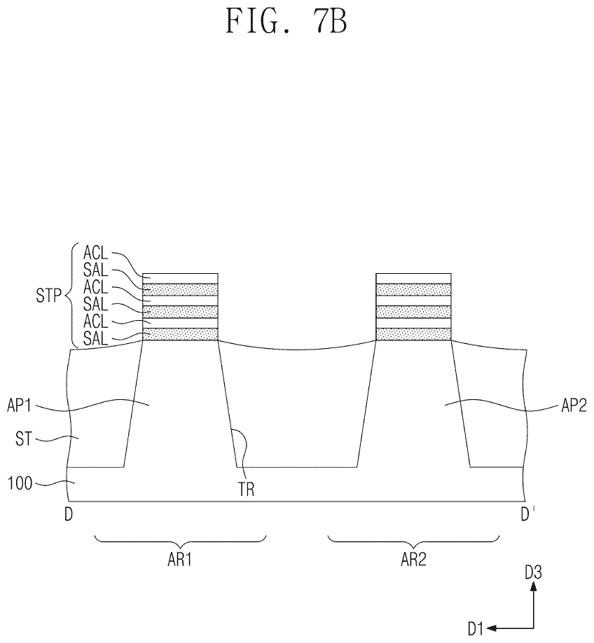

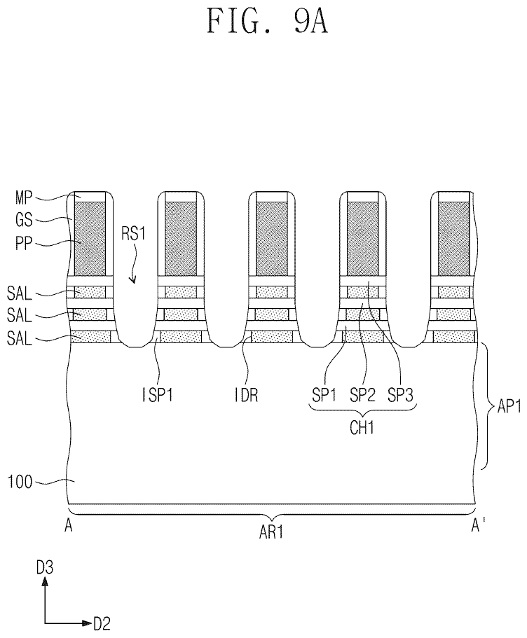

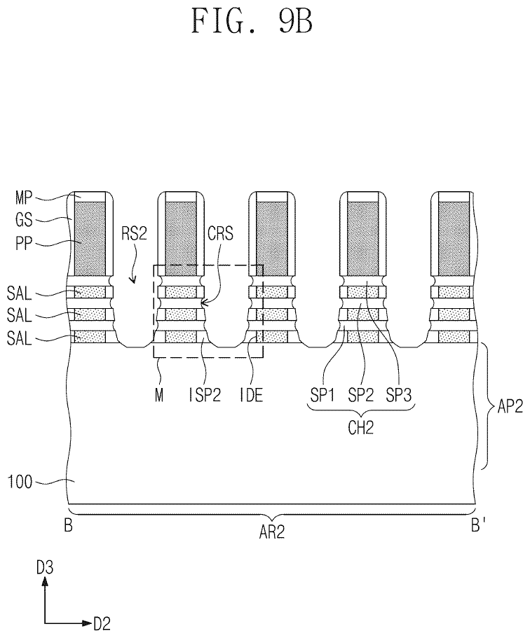

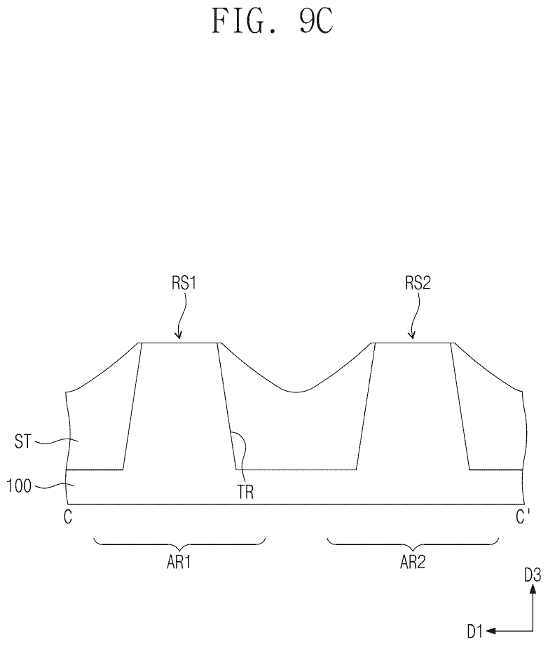

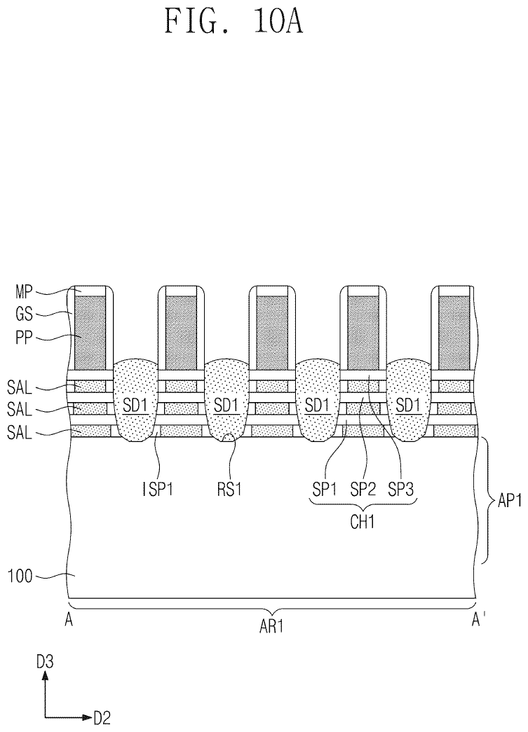

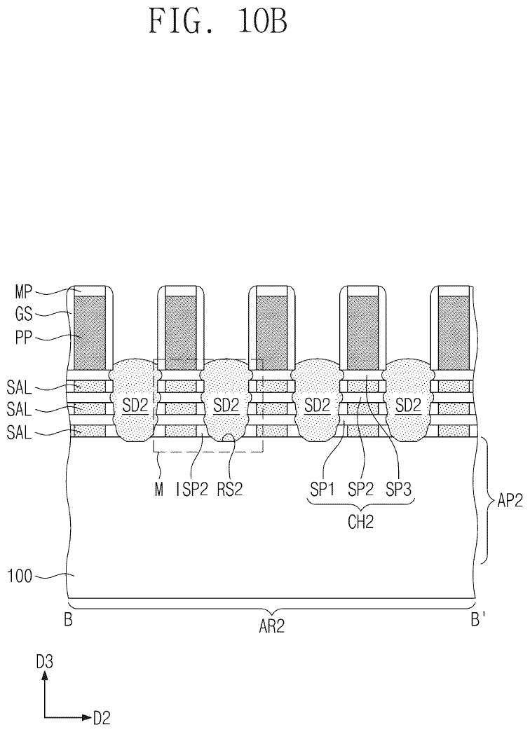

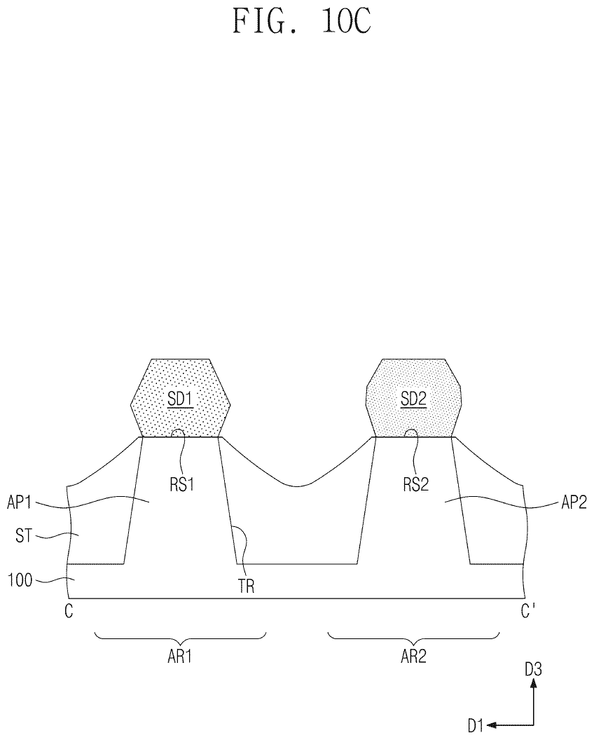

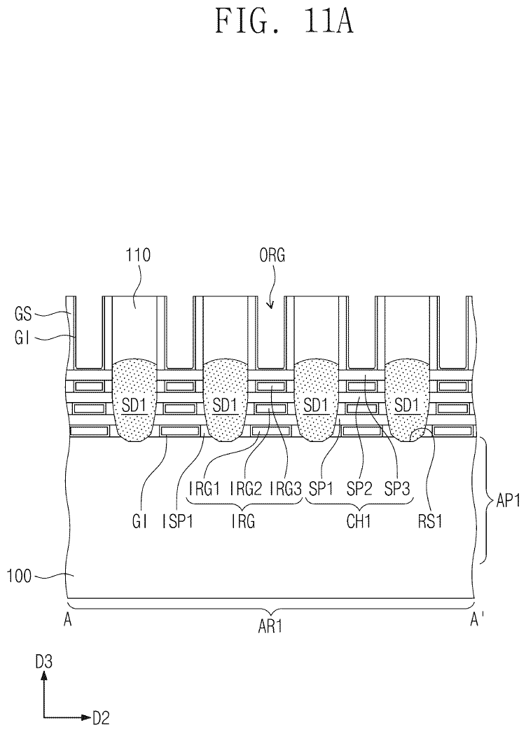

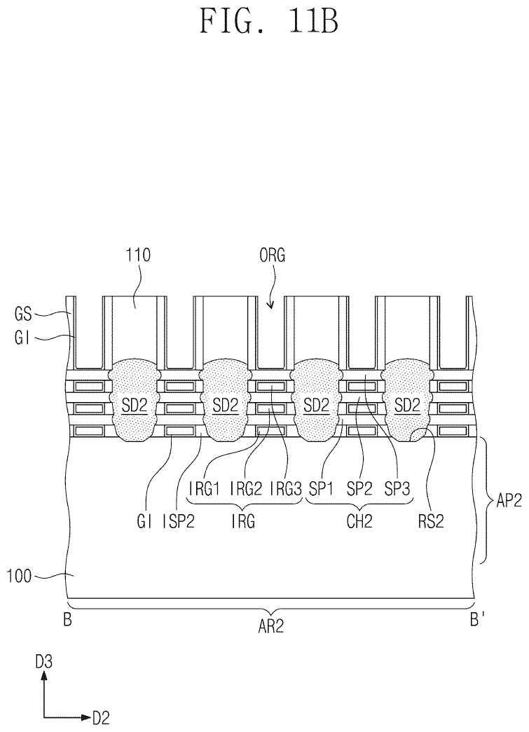

FIGS. 7A to 12D are cross-sectional views for describing a method for manufacturing a semiconductor device according to an example embodiment of the inventive concepts. FIGS. 13 to 17 are enlarged diagrams for describing a method for forming region M of FIG. 10B. For example, FIGS. 7A, 8A, 9A, 10A, 11A and 12A are cross-sectional views corresponding to line A-A′ of FIG. 4. FIGS. 9B, 10B, 11B and 12B are cross-sectional views corresponding to line B-B′ of FIG. 4. FIGS. 9C, 10C, 11C and 12C are cross-sectional views corresponding to line C-C′ of FIG. 4. FIGS. 7B, 8B, 11D and 12D are cross-sectional views corresponding to line D-D′ of FIG. 4.

Referring to FIGS. 7A and 7B, the substrate 100 including the first and second active regions AR1 and AR2 may be provided. Active layers ACL and sacrificial layers SAL alternately stacked may be formed on the substrate 100. The active layers ACL may include one of silicon (Si), germanium (Ge), or silicon-germanium (SiGe), and the sacrificial layers SAL may include another one of silicon (Si), germanium (Ge) or silicon-germanium (SiGe).

The sacrificial layer SAL may include a material having etching selectivity for the active layer ACL. For example, the active layers ACL may include silicon (Si), and the sacrificial layers SAL may include silicon-germanium (SiGe). Each of the sacrificial layers SAL may have a germanium (Ge) concentration of about 10 at % to about 30 at %.

Mask patterns may be formed on the first and second active regions AR1 and AR2 of the substrate 100 respectively. The mask pattern may have a form of a line or a bar extending in the second direction D2.

The trench TR defining the first active pattern AP1 and the second active pattern AP2 may be formed by performing a patterning process using the mask patterns as etching masks. The first active pattern AP1 may be formed on the first active region AR1. The second active pattern AP2 may be formed on the second active region AR2.

A stack pattern STP may be formed on each of the first and second active patterns AP1 and AP2. The stack pattern STP may include the active layers ACL and the sacrificial layers SAL alternately stacked. The stack pattern STP may be formed together with the first and second active patterns AP1 and AP2 during the patterning process.

The element separation layer ST that fills the trench TR may be formed. For example, an insulating layer covering the first and second active patterns AP1 and AP2 and the stack patterns STP may be formed on a front surface of the substrate 100. The element separation layer ST may be formed by recessing the insulating layer until the stack patterns STP are exposed.

The element separation layer ST may include an insulating material such as a silicon oxide layer. The stack patterns STP may be exposed over the element separation layer ST. In other words, the stack patterns STP may vertically protrude over the element separation layer ST.

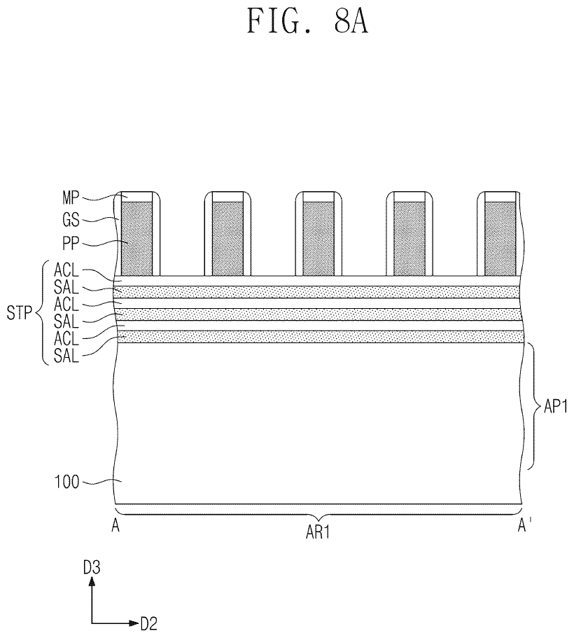

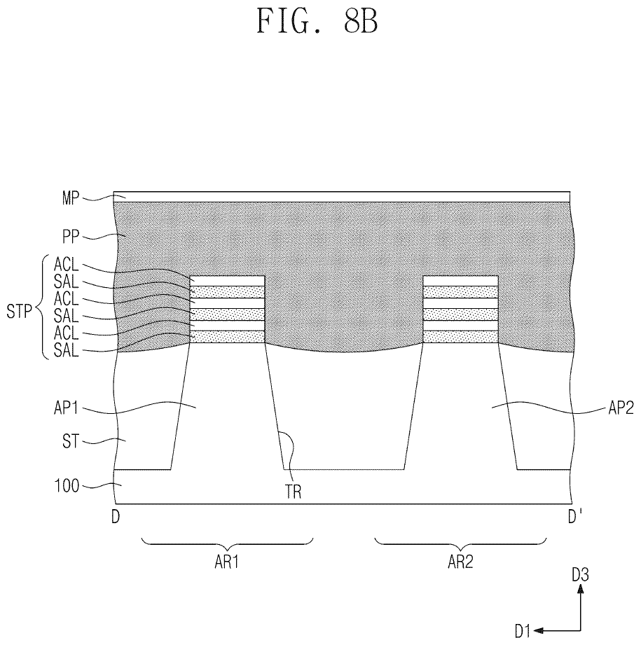

Referring to FIGS. 8A and 8B, sacrificial patterns PP crossing the stack patterns STP may be formed on the substrate 100. Each of the sacrificial patterns PP may be formed in a form of a line or a bar extending in the first direction D1. The sacrificial patterns PP may be arranged along the second direction D2 with the first pitch.

For example, forming the sacrificial patterns PP may include forming a sacrificial layer on the front surface of the substrate 100, forming hard-mask patterns MP on the sacrificial layer, and patterning the sacrificial layer using the hard-mask patterns MP as etching masks. The sacrificial layer may include polysilicon.

A pair of gate spacers GS may be formed on both sidewalls of each of the sacrificial patterns PP. Forming the gate spacers GS may include conformally forming a gate spacer layer on the front surface of the substrate 100, and anisotropically etching the gate spacer layer. According to an example embodiment of the inventive concepts, the gate spacer GS may be a multi-layer including at least two layers.

Referring to FIGS. 9A to 9C, the first recesses RS1 may be formed in the stack pattern STP on the first active pattern AP1. The second recesses RS2 may be formed in the stack pattern STP on the second active pattern AP2. During forming the first and second recesses RS1 and RS2, the element separation layer ST on both sides of each of the first and second active patterns AP1 and AP2 may be further recessed (see FIG. 9C).

For example, the first recesses RS1 may be formed by etching the stack pattern STP on the first active pattern AP1 by using the hard-mask patterns MP and the gate spacers GS as etching masks. The first recess RS1 may be formed between a pair of sacrificial patterns PP.

The first to third semiconductor patterns SP1, SP2, and SP3 sequentially stacked between the first recesses RS1 adjacent to each other may be formed from the active layers ACL, respectively. The first to third semiconductor patterns SP1, SP2, and SP3 between the first recesses RS1 adjacent to each other may constitute the first channel pattern CH1.

For example, the first recess RS1 may be formed between the sacrificial patterns PP, and a width in the second direction D2 of the first recess RS1 may become smaller in a direction getting closer to the substrate 100. The sacrificial layers SAL may be exposed by the first recess RS1. A process of selectively etching the exposed sacrificial layers SAL may be performed. The etching process may include a wet etching process of selectively removing only silicon-germanium. A first indent region IDR may be formed by indenting each of the sacrificial layers SAL in the etching process.

The first inner spacer ISP1 that fills the first indent region IDR may be formed. Forming the first inner spacer ISP1 may include forming an insulating layer that fills the first indent region IDR through the first recess RS1, and wet etching the insulating layer exposed outside the first indent region IDR. The insulating layer may include at least one of a silicon oxide layer, a silicon nitride layer or a silicon oxynitride layer. The first inner spacers ISP1 may be interposed between the first recess RS1 and the sacrificial layers SAL, respectively.

Referring back to FIGS. 9A to 9C, the second recesses RS2 in the stack pattern STP on the second active pattern AP2 may be formed in processes similar to the processes of forming the first recesses RS1. Second indent regions IDE may be formed by performing a process of selectively etching the sacrificial layers SAL exposed by the second recess RS2. The second recess RS2 may have an inner sidewall having a wavy shape due to the second indent regions IDE. The second inner spacer ISP2 may be formed in the second indent regions IDE on the second active pattern AP2. The first to third semiconductor patterns SP1, SP2, and SP3 between the second recesses RS2 adjacent to each other may constitute the second channel pattern CH2. Forming the second inner spacers ISP2 will be described with reference to FIGS. 10A to 10C and 13 to 17 in detail.

Referring to FIGS. 10A to 10C, the first source/drain patterns SD1 may be respectively formed in the first recesses RS1. For example, an epitaxial layer that fills the first recess RS1 may be formed by performing a SEG process using an inner sidewall of the first recess RS1 as a seed layer. The epitaxial layer may be grown using the first to third semiconductor patterns SP1, SP2, and SP3 and the substrate 100 exposed by the first recess RS1 as seeds. For example, the SEG process may include a chemical vapor deposition (CVD) process or a molecular beam epitaxy (MBE) process.

According to an example embodiment of the inventive concepts, the first source/drain pattern SD1 may include the same semiconductor element (e.g., Si) as the substrate 100. During forming the first source/drain pattern SD1, an impurity (e.g., phosphorous, arsenic or antimony) that causes the first source/drain pattern SD1 to have an N-type may be in-situ injected. For another example, after forming the first source/drain pattern SD1, the impurity may be injected into the first source/drain pattern SD1.

The second source/drain patterns SD2 may be formed in the second recesses RS2, respectively. For example, the second source/drain pattern SD2 may be formed by performing a SEG process using an inner sidewall of the second recess RS2 as a seed layer.

According to an example embodiment of the inventive concepts, the second source/drain pattern SD2 may include a semiconductor element (e.g., SiGe) having a greater lattice parameter than a semiconductor element of the substrate 100. During forming the second source/drain pattern SD2, an impurity (e.g., boron, gallium, or indium) that causes the second source/drain pattern SD2 to have a P-type may be in-situ injected. For another example, after forming the second source/drain pattern SD2, the impurity may be injected into the second source/drain pattern SD2.

FIGS. 13 to 17 are enlarged diagrams for describing a method for forming region M of FIG. 9B and region M of FIG. 10B. Referring to FIG. 13, the second recess RS2 may be formed between the sacrificial patterns PP. A width in the second direction D2 of the second recess RS2 may become smaller in a direction getting closer to the substrate 100. The second recess RS2 may be formed by partially removing an upper surface of the second active pattern AP2.

The sacrificial layers SAL may be exposed by the second recess RS2. A process of selectively etching the exposed sacrificial layers SAL may be performed. The etching process may include a wet etching process of selectively removing only silicon-germanium. Each of the sacrificial layers SAL may be indented in the etching process to form the second indent region IDE. A sidewall of the sacrificial layer SAL may be concave due to the second indent region IDE.

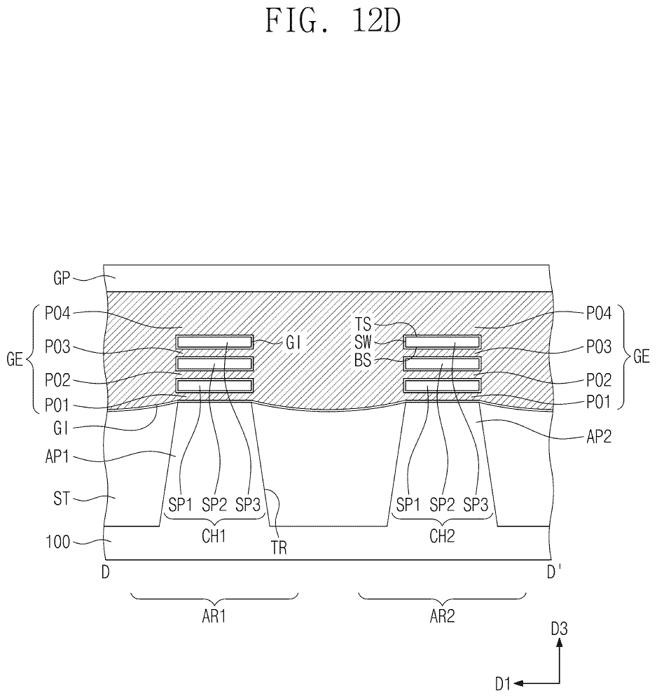

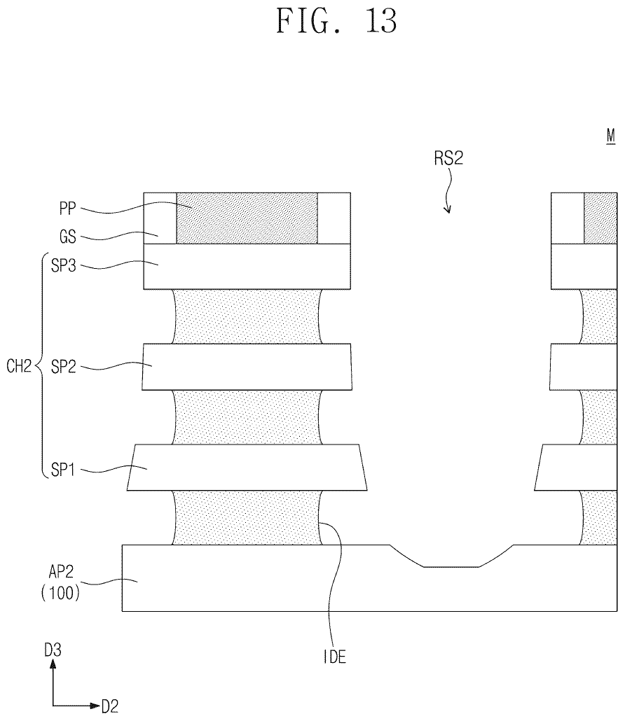

Referring to FIG. 14, a preliminary insulating layer ISPL that fills the second indent region IDE may be formed. Forming the preliminary insulating layer ISPL may be forming the preliminary insulating layer ISPL that fills the second indent region IDE through the second recess RS2. The preliminary insulating layer ISPL may be formed by performing a chemical vapor deposition (CVD) process. The preliminary insulating layer ISPL may include a silicon nitride-based insulating material. For example, the insulating material may include at least one selected from the group consisting of SiN, SiCN, SiOCN and SiBCN.

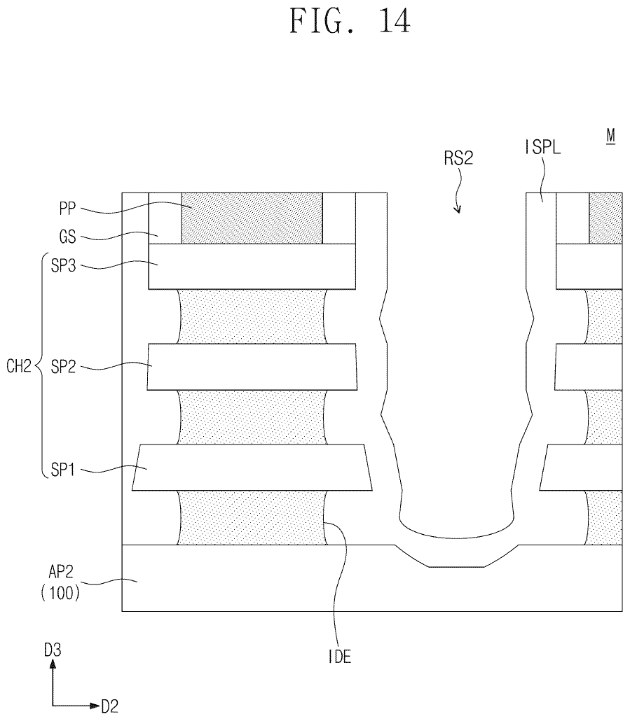

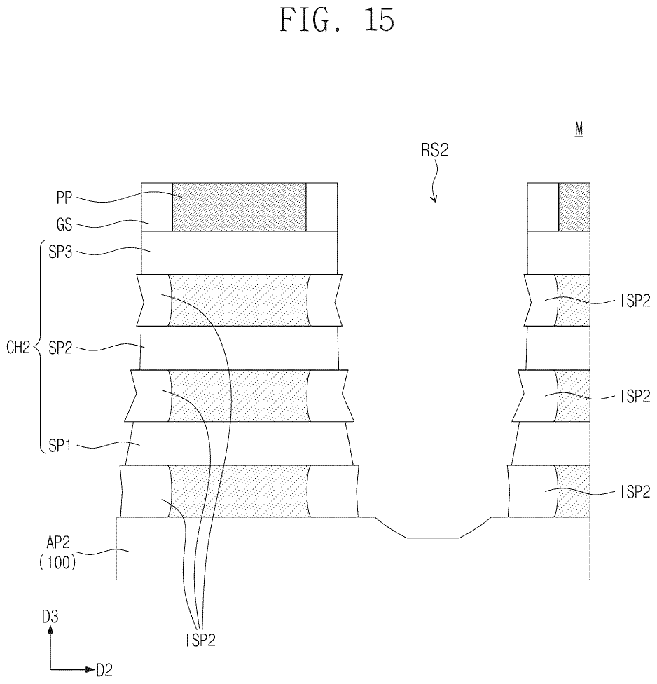

Referring to FIG. 15, the second inner spacer ISP2 may be formed by wet etching the preliminary insulating layer ISPL exposed outside the second indent region IDE. The second active pattern AP2 and the second channel pattern CH2 except for the preliminary insulating layer ISPL may have no loss depending on etching selectivity of the wet etching process. A shape of one side surface of the second inner spacer ISP2 formed through the wet etching process may correspond to a shape of an inner side surface of the preliminary insulating layer ISPL described above. The second inner spacers ISP2 may be interposed between the second recess RS2 and the sacrificial layers SAL, respectively.

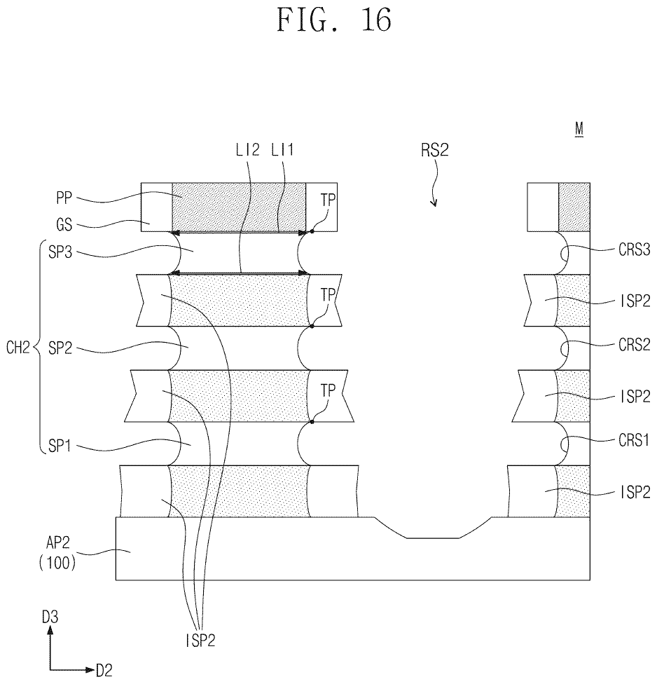

Referring to FIG. 16, after forming the second inner spacers ISP2, the first to third semiconductor patterns SP1, SP2, and SP3 of the second channel pattern CH2 may be exposed by the second recess RS2. A process of selectively etching the first to third semiconductor patterns SP1, SP2, and SP3 of the second channel pattern CH2 exposed by the second recess RS2 may be performed. The etching process may include a wet etching process of selectively removing only silicon.

First to third channel recesses CRS1, CRS2 and CRS3 may be formed by partially etching each of the first to third semiconductor patterns SP1, SP2, and SP3. For example, a first channel recess CRS1 may be formed by horizontally recessing the first semiconductor pattern SP1, a second channel recess CRS2 may be formed by horizontally recessing the second semiconductor pattern SP2, and a third channel recess CRS3 may be formed by horizontally recessing the third semiconductor pattern SP3. The second recess RS2 may have an inner sidewall having a wavy shape due to the first to third channel recesses CRS1, CRS2 and CRS3.

A first concave sidewall may be formed in the first semiconductor pattern SP1 by the first channel recess CRS1, a second concave sidewall may be formed in the second semiconductor pattern SP2 by the second channel recess CRS2, and a third concave sidewall may be formed in the third semiconductor pattern SP3 by the third channel recess CRS3. Each of the first to third semiconductor patterns SP1, SP2, and SP3 may have the tip TP on an upper surface thereof due to a corresponding one of the first to third channel recesses CRS1, CRS2 and CRS3.

For example, an upper surface of the third semiconductor pattern SP3 may have the first length LI1 due to the third channel recess CRS3, and a lower surface of the third semiconductor pattern SP3 may have the second length LI2 due to the third channel recess CRS3. The second length LI2 and the first length LI1 may be substantially the same.

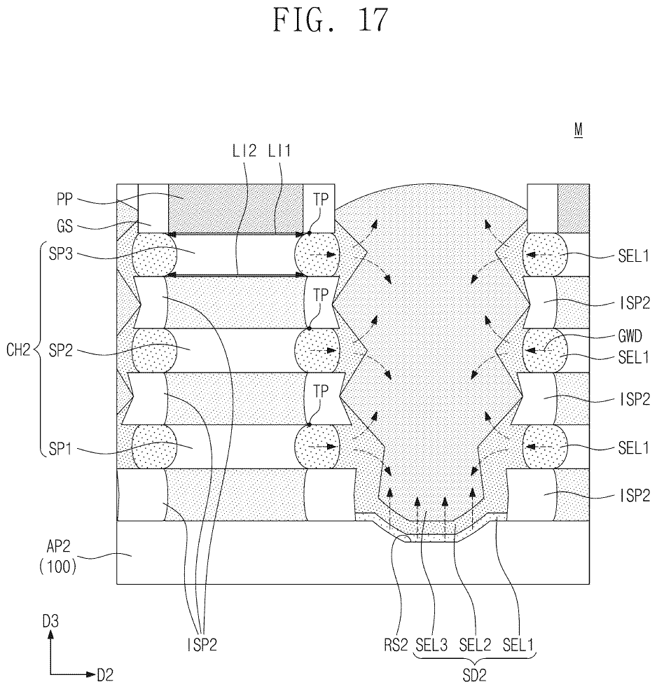

Referring to FIG. 17, a SEG process may be performed by using the second active pattern AP2 and the first to third semiconductor patterns SP1, SP2, and SP3 in the second recess RS2 as seed layers. Accordingly, the first semiconductor layer SEL1 may be grown in the second recess RS2.

The first semiconductor layer SEL1 grown on the first to third semiconductor patterns SP1, SP2, and SP3 may fill the first to third channel recesses CRS1, CRS2 and CRS3. The first semiconductor layer SEL1 grown on the second active pattern AP2 may fill a lower portion of the second recess RS2.

The first semiconductor layer SEL1 on the first to third semiconductor patterns SP1, SP2, and SP3 may be grown more in a <111> direction. Meanwhile, because the second inner spacers ISP2 do not operate as seeds, the first semiconductor layer SEL1 may not be grown on the second inner spacers ISP2.

According to an example embodiment of the inventive concepts, even when a growth direction of the first semiconductor layer SEL1 is the <111> direction, the second semiconductor layer SEL2 may be formed so as to cover all surfaces of the second inner spacers ISP2 by using the first to third channel recesses CRS1, CRS2 and CRS3. Time for which the second semiconductor layer SEL2 completely covers the second inner spacer ISP2 may be secured by increasing a horizontal growth length of the first semiconductor layer SEL1 by using the first to third channel recesses CRS1, CRS2 and CRS3. That is, the second semiconductor layer SEL2 may cover the first semiconductor layer SEL1, the second inner spacers ISP2 and a portion of the gate spacer GS.

A SEG process may be performed so as to completely fill the second recess RS2 by using the second semiconductor layer SEL2 as a seed layer. Accordingly, the third semiconductor layer SEL3 may be grown in the second recess RS2. The third semiconductor layer SEL3 having a relatively high germanium (Ge) concentration may be formed so as to occupy a large volume by sequentially forming the first and second semiconductor layers SEL1 and SEL2. That is, according to an example embodiment of the inventive concepts, the third semiconductor layer SEL3 having the relatively high germanium (Ge) concentration may occupy a larger volume in the second source/drain pattern SD2 than the first and second semiconductor layers SEL1 and SEL2 having relatively low germanium (Ge) concentrations in the second source/drain pattern SD2.

Referring back to FIG. 17, forming the second source/drain pattern SD2 according to an example embodiment of the inventive concepts may be performed by forming the first semiconductor layer SEL1 using the first to third channel recesses CRS1, CRS2 and CRS3 and forming the second semiconductor layer SEL2 so as to completely cover the second inner spacer ISP2. Accordingly, generation of parasitic capacitance and leakage current caused by the second inner spacer ISP2 may be reduced or prevented. Thus, the method for manufacturing a semiconductor device according to some example embodiments of the inventive concepts may guarantee improved electrical characteristics of the device.

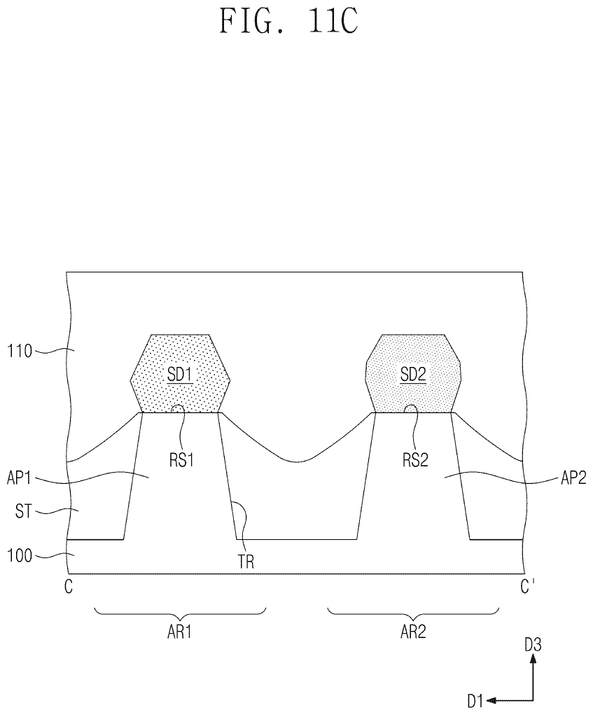

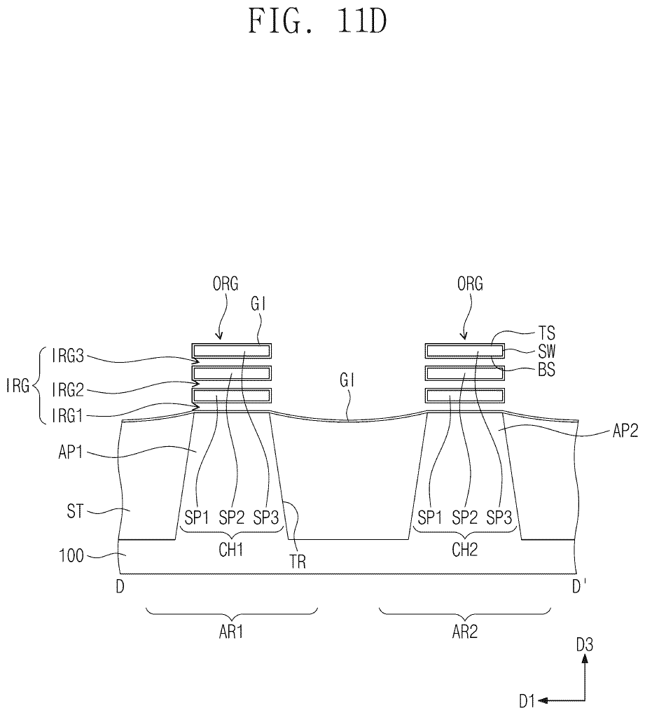

Referring to FIGS. 11A to 11D, the first interlayered insulating layer 110 covering the first and second source/drain patterns SD1 and SD2, the hard mask patterns MP and the gate spacers GS may be formed. For example, the first interlayered insulating layer 110 may include a silicon oxide layer.

The first interlayered insulating layer 110 may be planarized until upper surfaces of the sacrificial patterns PP are exposed. Planarizing the first interlayered insulating layer 110 may be performed by using an etch-back process or a chemical mechanical polishing (CMP) process. The hard mask patterns MP may be all removed during the planarizing process. As a result, an upper surface of the first interlayered insulating layer 110 may be coplanar with the upper surfaces of the sacrificial patterns PP and upper surfaces of the gate spacers GS.

The exposed sacrificial patterns PP may be selectively removed. An outer region ORG exposing the first and second channel patterns CH1 and CH2 may be formed by removing the sacrificial patterns PP (see FIG. 11D). Removing the sacrificial patterns PP may include wet etching using etchant that selectively etches polysilicon.

Inner regions IRG may be formed by selectively removing the sacrificial layers SAL exposed through the outer region ORG (see FIG. 11D). For example, the first to third semiconductor patterns SP1, SP2, and SP3 may remain and only sacrificial layers SAL may be removed by performing an etching process of selectively etching the sacrificial layers SAL. The etching process may have a relatively high etch-rate for silicon-germanium having a relatively high germanium concentration. For example, the etching process may have a relatively high etch-rate for silicon-germanium having a germanium concentration greater than about 10 at %.

The sacrificial layers SAL on the first and second active regions AR1 and AR2 may be removed during the etching process. The etching process may be wet etching. Etchant used in the etching process may rapidly remove the sacrificial layer SAL having a relatively high germanium concentration.

Referring back to FIG. 11D, only stacked first to third semiconductor patterns SP1, SP2, and SP3 may remain on each of the first and second active patterns AP1 and AP2 by selectively removing the sacrificial layers SAL. First to third inner regions IRG1, IRG2, and IRG3 may be formed through regions in which the sacrificial layers SAL are removed, respectively.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

Referring back to FIGS. 11A to 11D, the gate insulating layer GI may be formed on the exposed first to third semiconductor patterns SP1, SP2, and SP3. The gate insulating layer GI may be formed so as to surround each of the first to third semiconductor patterns SP1, SP2, and SP3. The gate insulating layer GI may be formed in each of the first to third inner regions IRG1, IRG2, and IRG3. The gate insulating layer GI may be formed in the outer region ORG.

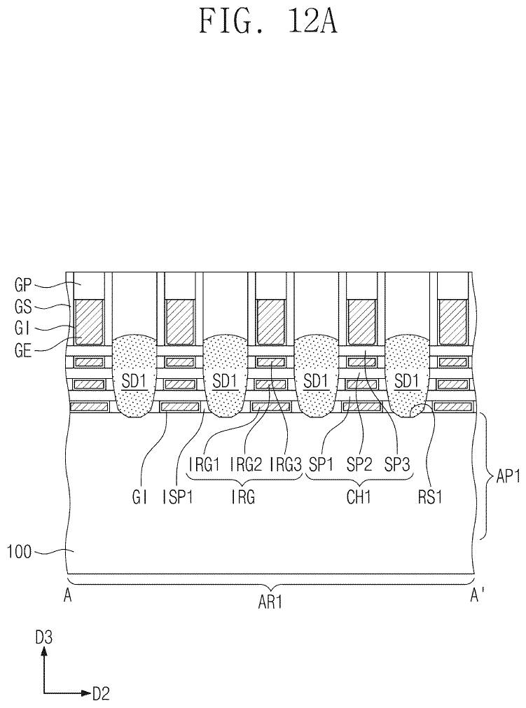

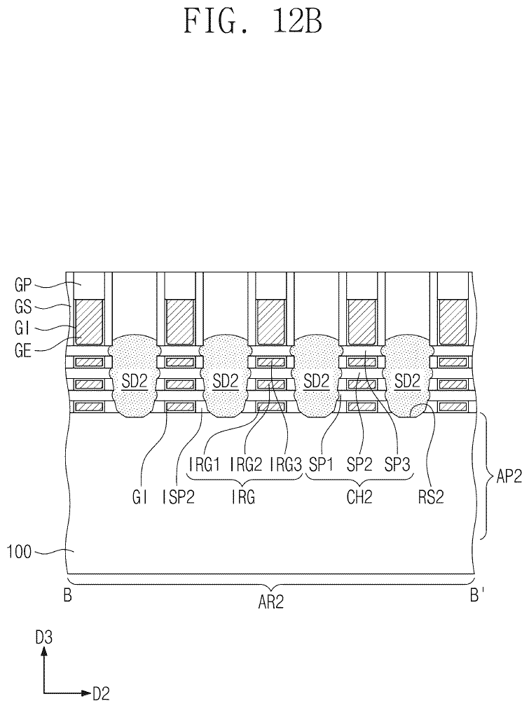

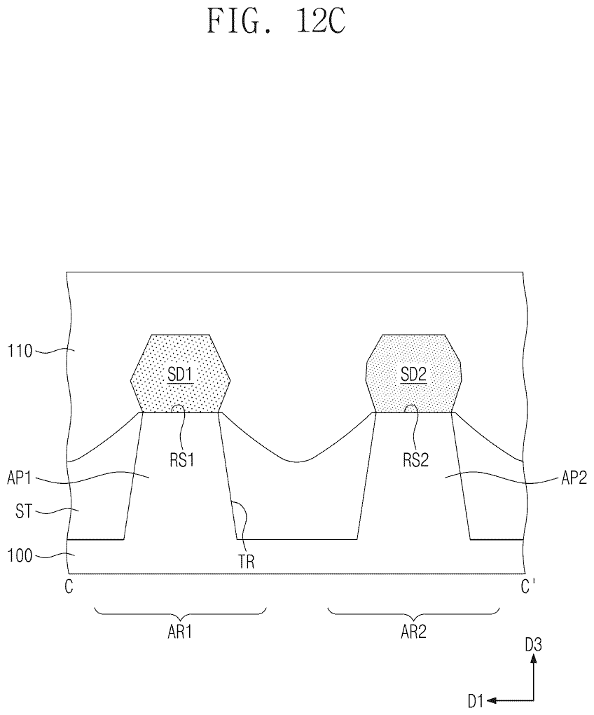

Referring to FIGS. 12A to 12D, the gate electrode GE may be formed on the gate insulating layer GI. The gate electrode GE may include the first to third inner electrodes PO1, PO2, and PO3 formed in the first to third inner regions IRG1, IRG2, and IRG3, respectively, and the outer electrode PO4 formed in the outer region ORG. The gate electrode GE may be recessed to reduce a height thereof. The gate capping pattern GP may be formed on the recessed gate electrode GE.

Referring back to FIGS. 5A to 5D, the second interlayered insulating layer 120 may be formed on the first interlayered insulating layer 110. The second interlayered insulating layer 120 may include a silicon oxide layer. The active contacts AC penetrating the first interlayered insulating layer 110 and the second interlayered insulating layer 120 to be electrically connected to the first and second source/drain patterns SD1 and SD2 may be formed. The gate contact GC penetrating the second interlayered insulating layer 120 and the gate capping pattern GP to be electrically connected to the gate electrode GE may be formed.

Forming each of the active contact AC and the gate contact GC may include forming the barrier pattern BM and forming the conductive pattern FM on the barrier pattern BM. The barrier pattern BM may be conformally formed, and may include a metal layer/metal nitride layer. The conductive pattern FM may include low-resistive metal.

The separation structures DB may be formed on the first boundary BD1 and the second boundary BD2 of the single height cell SHC, respectively. The separation structure DB may penetrate the gate electrode GE to extend from the second interlayered insulating layer 120 to an inside of the active pattern AP1 or AP2. The separation structure DB may include an insulating material such as a silicon oxide layer or a silicon nitride layer.

The third interlayered insulating layer 130 may be formed on the active contacts AC and the gate contacts GC. The first metal layer M1 may be formed in the third interlayered insulating layer 130. The fourth interlayered insulating layer 140 may be formed on the third interlayered insulating layer 130. The second metal layer M2 may be formed in the fourth interlayered insulating layer 140.

In a semiconductor device according to an example embodiment of the inventive concepts, an inner spacer may be formed between a source/drain pattern and a gate electrode on a PMOSFET region to reduce parasitic capacitance and leakage current generated on a PMOSFET element. In addition, an electric short phenomenon between the gate electrode and the source/drain pattern may be reduced.

The source/drain pattern on the PMOSFET region may include a plurality of layers having different germanium concentrations to reduce, together with the inner spacer, the parasitic capacitance and the leakage current generated on the PMOSFET element. That is, electrical characteristics of the semiconductor device according to an example embodiment of the inventive concepts may be improved.

Although some example embodiments of the present inventive concepts have been described, it is understood that the present invention should not be limited to these example embodiments but various changes and modifications can be made by one ordinary skilled in the art within the spirit and scope of the present inventive concepts as hereinafter claimed. Therefore, it should be understood that the example embodiments described above are exemplary in all respects and are not intended to be limiting.

What is claimed is:

1. A semiconductor device comprising:
a substrate including an active pattern;
a channel pattern being on the active pattern, the channel pattern including a plurality of semiconductor patterns vertically spaced apart from each other;
a source/drain pattern connected to the plurality of semiconductor patterns;
a gate electrode being on the plurality of semiconductor patterns, the gate electrode including an inner electrode and an outer electrode, the inner electrode interposed between a pair semiconductor patterns that are adjacent to each other, among the plurality of semiconductor patterns, the outer electrode on an uppermost semiconductor pattern among the plurality of semiconductor patterns; and
an inner spacer interposed between the inner electrode and the source/drain pattern,
wherein the source/drain pattern includes a first semiconductor layer in contact with the plurality of semiconductor patterns, a second semiconductor layer on the first semiconductor layer, and a third semiconductor layer on the second semiconductor layer,
the inner spacer has a first tip length in a first direction,
the first semiconductor layer has a second tip length in the first direction, and
the first tip length is greater than the second tip length.

2. The semiconductor device of claim 1, wherein
the inner spacer has a third tip length in an opposite direction of the first direction,
the first semiconductor layer and the second semiconductor layer have a fourth tip length in the opposite direction of the first direction, and
the fourth tip length is greater than the third tip length.

3. The semiconductor device of claim 2, wherein the fourth tip length is greater than the first to third tip lengths.

4. The semiconductor device of claim 1, wherein
the source/drain pattern comprises silicon-germanium (SiGe), and
the third semiconductor layer has a greater germanium (Ge) concentration than the first semiconductor layer and the second semiconductor layer.

5. The semiconductor device of claim 4, wherein the second semiconductor layer has a greater germanium (Ge) concentration than the first semiconductor layer.

6. The semiconductor device of claim 4, wherein
the first semiconductor layer has a germanium (Ge) concentration of about 2 at % to about 8 at %,
the second semiconductor layer has a germanium (Ge) concentration of about 10 at % to about 20 at %, and
the third semiconductor layer has a germanium (Ge) concentration of about 30 at % to about 70 at %.

7. The semiconductor device of claim 1, wherein
the first semiconductor layer of the source/drain pattern protrudes toward each of the plurality of semiconductor patterns, and
the first semiconductor layer has a side surface convex toward each of the plurality of semiconductor patterns.

8. The semiconductor device of claim 1, wherein each of the plurality of semiconductor patterns comprises concave sidewalls.

9. The semiconductor device of claim 1, wherein
the source/drain pattern further comprises the first semiconductor layer interposed between the active pattern and the second semiconductor layer, and
the first semiconductor layer is at a bottom portion of the source/drain pattern.

10. The semiconductor device of claim 1, wherein
an upper surface of an uppermost semiconductor pattern among the plurality of semiconductor patterns has a first length in the first direction,
a lower surface of the uppermost semiconductor pattern among the plurality of semiconductor patterns has a second length in the first direction,
the outer electrode has a third length in the first direction,
the inner electrode has a fourth length in the first direction, and
each of the first length and the second length is greater than the third length and the fourth length.

11. The semiconductor device of claim 10, wherein a minimum length in the first direction of the uppermost semiconductor pattern among the plurality of semiconductor patterns is equal to or greater than each of the third length and the fourth length.

12. The semiconductor device of claim 1, wherein the inner spacer comprises a silicon nitride-based insulating material.

13. The semiconductor device of claim 12, wherein the silicon nitride-based insulating material comprises at least one selected from the group consisting of SiN, SiCN, SiOCN and SiBCN.

14. A semiconductor device comprising:
a substrate including a PMOSFET region;
an active pattern on the PMOSFET region;
a channel pattern being on the active pattern, the channel pattern including a plurality of semiconductor patterns vertically spaced apart from each other;
a source/drain pattern connected to the plurality of semiconductor patterns;
a gate electrode being on the plurality of semiconductor patterns, the gate electrode including an inner electrode interposed between a pair of semiconductor patterns that are adjacent to each other, among the plurality of semiconductor patterns, an outer electrode on an uppermost semiconductor pattern among the plurality of semiconductor patterns;
a gate insulating layer between the gate electrode and the semiconductor patterns adjacent to each other; and
an inner spacer interposed between the source/drain pattern and the gate insulating layer surrounding the inner electrode,
wherein the source/drain pattern includes a first semiconductor layer in contact with each of the plurality of semiconductor patterns,
the inner spacer has a first horizontal width in a first direction,
the first semiconductor layer has a second horizontal width in the first direction, and
the second horizontal width is different from the first horizontal width.

15. The semiconductor device of claim 14, wherein the first horizontal width is greater than the second horizontal width.

16. The semiconductor device of claim 14, wherein the second horizontal width is about 2 nm to about 6 nm.

17. The semiconductor device of claim 14, wherein
the source/drain pattern further comprises a second semiconductor layer on the first semiconductor layer and a third semiconductor layer on the second semiconductor layer,
an upper surface of each of the plurality of semiconductor patterns comprises a tip, and
an inner side surface of the second semiconductor layer is spaced farther apart from the tip in the first direction than one side surface of the inner spacer.

18. A semiconductor device comprising:
a first active pattern on a first active region of a substrate and a second active pattern on a second active region of the substrate;
an element separation layer configured to fill a trench defining the first and second active patterns;
a first channel pattern on the first active pattern and a second channel pattern on the second active pattern, each of the first and second channel patterns including a first semiconductor pattern, a second semiconductor pattern and a third semiconductor pattern vertically spaced apart from each other;
a first source/drain pattern connected to the first channel pattern and a second source/drain pattern connected to the second channel pattern;
a gate electrode on the first to third semiconductor patterns;
a gate insulating layer between the first to third semiconductor patterns and the gate electrode;
a first inner spacer interposed between the gate insulating layer and the first source/drain pattern, and a second inner spacer interposed between the gate insulating layer and the second source/drain pattern;
a gate spacer on a sidewall of the gate electrode;
a gate capping pattern on an upper surface of the gate electrode;
an interlayered insulating layer on the gate capping pattern;
an active contact penetrating the interlayered insulating layer to be electrically connected to each of the first source/drain pattern and the second source/drain pattern;
a metal-semiconductor compound layer interposed between the active contact and the first source/drain pattern, and between the active contact and the second source/drain pattern;
a gate contact penetrating the interlayered insulating layer and the gate capping pattern to be electrically connected to the gate electrode;
a first metal layer being on the interlayered insulating layer, the first metal layer including power wires, the power wires electrically connected to the active contact and the gate contact; and
a second metal layer on the first metal layer,
wherein the second metal layer includes second wires electrically connected to the first metal layer,
the second active region is a PMOSFET region,
the second source/drain pattern includes a first semiconductor layer in contact with the first to third semiconductor patterns, a second semiconductor layer on the first semiconductor layer, and a third semiconductor layer on the second semiconductor layer,
the second inner spacer has a silicon nitride-based insulating material, and
the second source/drain pattern is spaced apart from the gate electrode by the second inner spacer.

19. The semiconductor device of claim 18, wherein the silicon nitride-based insulating material comprises at least one selected from the group consisting of SiN, SiCN, SiOCN and SiBCN.

20. The semiconductor device of claim 18, wherein
the second source/drain pattern comprises silicon-germanium (SiGe),
the third semiconductor layer has a greater germanium (Ge) concentration than the first semiconductor layer and the second semiconductor layer,
the second inner spacer has a first horizontal width in a first direction,
the first semiconductor layer has a second horizontal width in the first direction, and
the first horizontal width and the second horizontal width are same.
